(19) United States
(12) Patent Application Publication
(10) Pub. No.: US 2024/0324324 A1
(43) Pub. Date: Sep. 26, 2024

(54) DISPLAY APPARATUS

(71) Applicant: Samsung Display Co., Ltd., Yongin-Si, Gyeonggi-Do (KR)

(72) Inventors: Jinho Ju, Yongin-si (KR); Younjoon Kim, Yongin-si (KR); Minjeong Oh, Yongin-si (KR); Kijune Lee, Yongin-si (KR); Sungeun Lee, Yongin-si (KR); Jonghyun Choi, Yongin-si (KR)

(21) Appl. No.: 18/600,780

(22) Filed: Mar. 11, 2024

(30) Foreign Application Priority Data
Mar. 24, 2023 (KR) 10-2023-0039062
Jun. 12, 2023 (KR) 10-2023-0075055

(51) Int. Cl. H10K 59/124; G09G 3/3233

(52) U.S. Cl. CPC H10K 59/124; G09G 3/3233; G09G 2300/0819; G09G 2300/0842; G09G 2300/0861; G09G 2330/021

(57) ABSTRACT

For a display apparatus with excellent durability, the display apparatus includes a substrate, a first organic insulating layer disposed on the substrate, a first conductive pattern disposed on the first organic insulating layer, a first inorganic insulating layer interposed between the first organic insulating layer and the first conductive pattern and patterned to have a same shape as the first conductive pattern, and a first transparent conductive layer disposed on the first conductive pattern and patterned to have a same shape as the first conductive pattern.

### CROSS-REFERENCE TO RELATED APPLICATIONS

This application is based on and claims priority, under 35 U.S.C. § 119, to Korean Patent Application No. 10-2023-0039062 filed on Mar. 24, 2023, and to Korean Patent Application No. 10-2023-0075055 filed on Jun. 12, 2023 in the Korean Intellectual Property Office, the disclosures of which are incorporated by reference herein in their entireties.

### BACKGROUND

### 1. Field

One or more embodiments relate to a display apparatus, and more particularly, to a display apparatus with excellent durability.

### 2. Description of the Related Art

Generally, in a display apparatus such as an organic light-emitting display apparatus, thin-film transistors are arranged in each (sub) pixel to control brightness and the like of each (sub) pixel. The thin-film transistors are configured to control brightness and the like of a corresponding (sub) pixel according to data signals transferred thereto.

### SUMMARY

In display apparatuses according to the related art, there is a high probability that a defect occurs due to external impact.

The disclosure pertains to a display apparatus with improved durability.

Additional aspects will be set forth in part in the description which follows and, in part, will be apparent from the description, or may be learned by practice of the presented embodiments of the disclosure.

According to one or more embodiments, a display apparatus includes a substrate, a first organic insulating layer disposed on the substrate, a first conductive pattern disposed on the first organic insulating layer, a first inorganic insulating layer interposed between the first organic insulating layer and the first conductive pattern and patterned to have a same shape as the first conductive pattern, and a first transparent conductive layer disposed on the first conductive pattern and patterned to have a same shape as the first conductive pattern.

An outer lateral surface of the first transparent conductive layer and an outer lateral surface of the first conductive pattern may be flush.

An outer lateral surface of the first transparent conductive layer, an outer lateral surface of the first conductive pattern, and an outer lateral surface of the first inorganic insulating layer may be flush.

When viewed in a direction perpendicular to the substrate, an area of the first transparent conductive layer may be equal to an area of the first conductive pattern.

When viewed in a direction perpendicular to the substrate, an area of the first transparent conductive layer, an area of the first conductive pattern, and an area of the first inorganic insulating layer may be equal to each other.

The first transparent conductive layer may have a first hole exposing a portion of an upper surface of the first conductive pattern.

The display apparatus may further include a second organic insulating layer disposed on the first organic insulating layer to cover the first transparent conductive layer, wherein the second organic insulating layer may have a second hole aligned with the first hole.

When viewed in a direction perpendicular to the substrate, the second hole connects to the first hole to form a hole that continuously extends through the second organic insulating layer and the first transparent conductive layer.

An area of the first hole may be greater than an area of the second hole, the area being measured in a plane that is parallel to the plane of a top surface of the substrate.

An area of the first hole in a second interface between the first transparent conductive layer and the second organic insulating layer may be less than an area of the first hole in a virtual plane that divides the first transparent conductive layer into two parts in a thickness direction of the display apparatus.

An area of the first hole in the second interface may be equal to an area of the second hole in the second interface.

The display apparatus may further include a second conductive pattern disposed on the second organic insulating layer, wherein the second conductive pattern is in contact with an upper surface of the first conductive pattern through the first hole and the second hole.

The second conductive pattern may fill the first hole and the second hole.

The display apparatus may further include a second inorganic insulating layer interposed between the second organic insulating layer and the second conductive pattern, wherein an edge of the second inorganic insulating layer is aligned with an edge of the second conductive pattern.

An outer lateral surface of the second conductive pattern is flush with an outer lateral surface of the second inorganic insulating layer.

When viewed in a direction perpendicular to the substrate, an area of the second conductive pattern may be equal to an area of the second inorganic insulating layer.

The second inorganic insulating layer may have a third hole aligned with the second hole.

The second conductive pattern may be in contact with the upper surface of the first conductive pattern through the first hole, the second hole, and the third hole.

The display apparatus may further include a second transparent conductive layer disposed on the second conductive pattern, wherein an edge of the second transparent conductive layer may be flush with an edge of the second conductive pattern.

An outer lateral surface of the second transparent conductive layer may be flush with an outer lateral surface of the second conductive pattern.

When viewed in a direction perpendicular to the substrate, an area of the second transparent conductive layer may be equal to an area of the second conductive pattern.

These and/or other aspects will become apparent and more readily appreciated from the following description of the embodiments, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a portion of a display apparatus according to an embodiment;

FIG. 2 is an equivalent circuit diagram of a pixel included in the display apparatus of FIG. 1;

FIG. 3 is a schematic configuration view of positions of transistors, a capacitor and the like in pixels included in the display apparatus of FIG. 1;

FIGS. 4 to 10 are schematic configuration views of elements such as transistors and a capacitor, for each layer, of a display apparatus shown in FIG. 3;

FIG. 11 is a schematic cross-sectional view of the display apparatus shown in FIG. 3, taken along lines I-I′, II-II′, and III-III′;

FIG. 12 is an enlarged cross-sectional view of a portion A of FIG. 11;

FIGS. 13 to 17 are schematic cross-sectional views showing a process of manufacturing the portion A of the display apparatus;

FIG. 18 is an enlarged cross-sectional view of a portion B of FIG. 11; and

FIGS. 19 to 22 are schematic cross-sectional views showing a process of manufacturing the portion B of the display apparatus.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

As used herein, when various elements such as a layer, a region, a plate, and the like are disposed “on” another element, not only the elements may be disposed “directly on” the other element, but another element may be disposed therebetween. In addition, sizes of elements in the drawings may be exaggerated or reduced for convenience of explanation. As an example, the size and thickness of each element shown in the drawings are arbitrarily represented for convenience of description, and thus, the disclosure is not necessarily limited thereto.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another. As used herein, two surfaces being “flush” means two surfaces form a continuous flat plane without a step between them. Similarly, two edges being “flush” means two edges are aligned to form a continuous flat plane without a step between them.

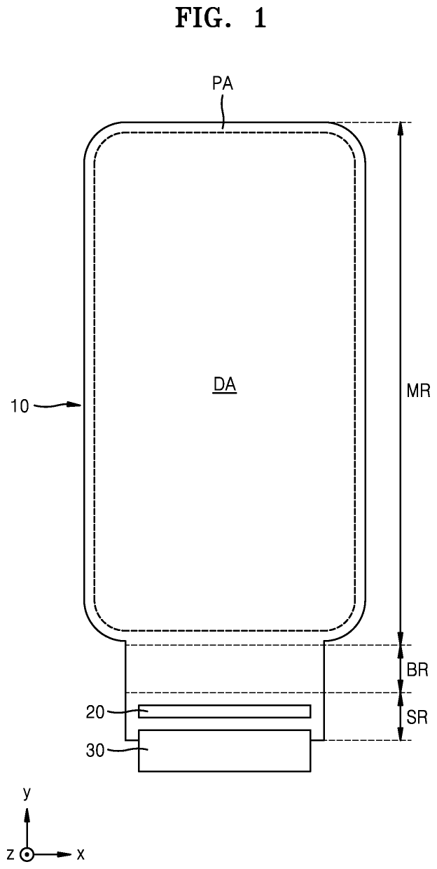

FIG. 1 is a schematic plan view of a portion of a display apparatus according to an embodiment. As shown in FIG. 1, the display apparatus according to an embodiment includes a display panel 10. As long as the display apparatus includes the display panel 10, any display apparatus may be used. As an example, the display apparatus may include various products such as smartphones, tablet computers, laptop computers, televisions, advertisement boards, or the like.

The display panel 10 includes a display area DA and a peripheral area PA outside the display area DA. The display area DA is a portion configured to display images, and a plurality of pixels may be arranged in the display area DA. When viewed in a direction approximately perpendicular to the display panel 10, the display area DA may have various shapes such as a circular shape, an elliptical shape, a polygon, and a shape of a specific figure. It is shown in FIG. 1 that the display area DA has an approximately rectangular shape having round corners.

The peripheral area PA may be arranged outside the display area DA. The width (in an x axis direction) of a portion of the peripheral area PA may be less than the width (in the x axis direction) of the display area DA. Through this structure, at least a portion of the peripheral area PA may be easily bent when needed as described below.

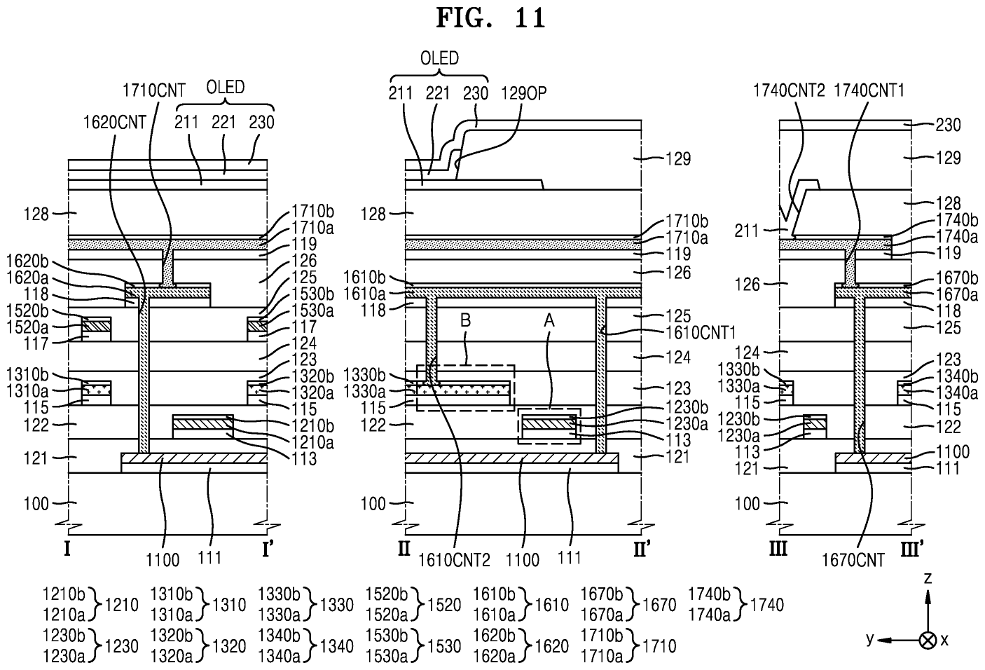

Because the display panel 10 includes a substrate 100 (see FIG. 11), it may be considered that the substrate 100 includes the display area DA and the peripheral area PA. Hereinafter, for convenience, description is made on the assumption that the substrate 100 includes the display area DA and the peripheral area PA.

In addition, when needed, the display panel 10 may include a main region MR, a bent region BR outside the main region MR, and a sub-region SR arranged opposite the main region MR around the bent region BR. Because bending of the display panel 10 is performed in the bent region BR, when viewed in a z axis direction, at least a portion of the sub-region BR may overlap the main region MR. The embodiment is not limited to a display apparatus that is bent, and is applicable to a display apparatus that is not bent. The sub-region SR may be a non-display area. Because the display panel 10 is bent in the bent region BR, when the display apparatus is viewed from the front surface thereof (in a-z direction), the non-display area may not be viewed, or an area of the non-display area that is viewed may be reduced even though the non-display area is viewed.

A driving chip 20 and the like may be arranged in the sub-region SR of the display panel 10. The driving chip 20 may include an integrated circuit configured to drive the display panel 10. Although the integrated circuit may be a data driving integrated circuit configured to generate data signals, the embodiment is not limited thereto.

The driving chip 20 may be arranged in the sub-region SR of the display panel 10. The driving chip 20 is disposed on the same surface as a display surface of the display area DA, but as described above, because the display panel 10 is bent in the bent region BR, the driving chip 20 may be disposed on the rear surface of the main region MR.

A printed circuit board 30 and the like may be attached to an end of the sub-region SR of the display panel 10. The printed circuit board 30 and the like may be electrically connected to the driving chip 20 and the like through a pad (not shown) on the substrate 100.

Hereinafter, although an organic light-emitting display apparatus is described as an example of the display apparatus according to an embodiment, the display apparatus is not limited thereto. In another embodiment, the display apparatus according to an embodiment may be an inorganic light-emitting display apparatus or a quantum-dot light-emitting display apparatus. As an example, an emission layer of a display element included in the display apparatus may include an organic material or an inorganic material. In addition, the display apparatus may include the emission layer and a quantum-dot layer located on a path of light emitted from the emission layer.

As described above, the display panel 10 includes the substrate 100. Various elements of the display panel 10 may be disposed on the substrate 100. The substrate 100 may include glass, metal, or polymer resin. In the case where the display panel 10 is bent in the bent region BR as described above, the substrate 100 needs to be flexible or bendable. In this case, the substrate 100 may include a polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers each including the polymer resin, and a barrier layer including an inorganic material (such as silicon oxide, silicon nitride, and silicon oxynitride) therebetween. However, various modifications may be made.

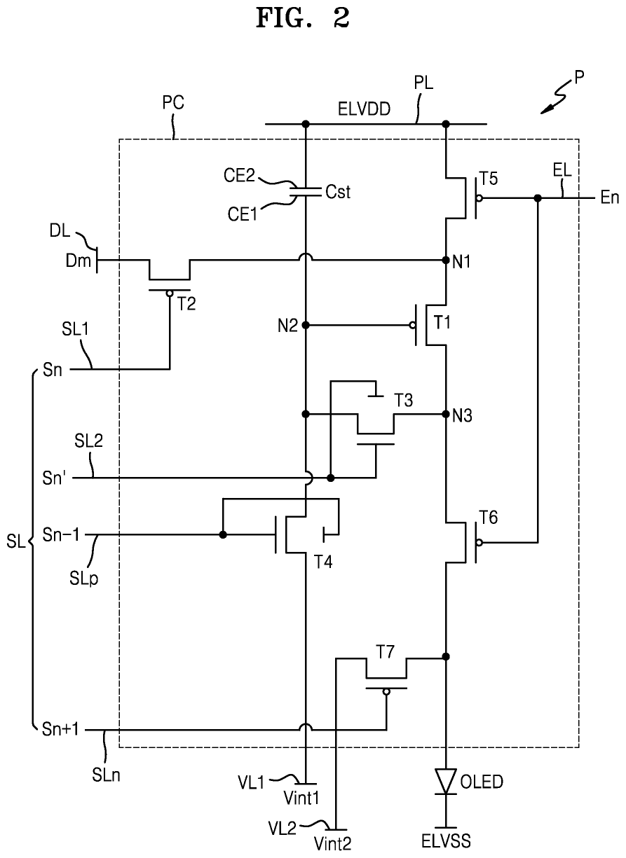

A plurality of pixels are arranged in the display area DA. Each of the pixels may denote a sub-pixel and include a display element such as an organic light-emitting diode OLED (see FIG. 2). The pixel may be configured to emit, for example, red, green, blue, or white light.

The pixel may be electrically connected to outer circuits arranged in the peripheral area PA. A scan driving circuit, an emission control driving circuit, a terminal, a driving power supply line, and an electrode power supply line, and the like may be arranged in the peripheral area PA. The scan driving circuit may be configured to provide scan signals to the pixel through a scan line. The emission control driving circuit may be configured to provide emission control signals to the pixel through an emission control line. The terminal arranged in the peripheral area PA of the substrate 100 may be exposed and electrically connected to the printed circuit board 30 by not being covered by the insulating layer. A terminal of the printed circuit board 30 may be electrically connected to a terminal of the display panel 10.

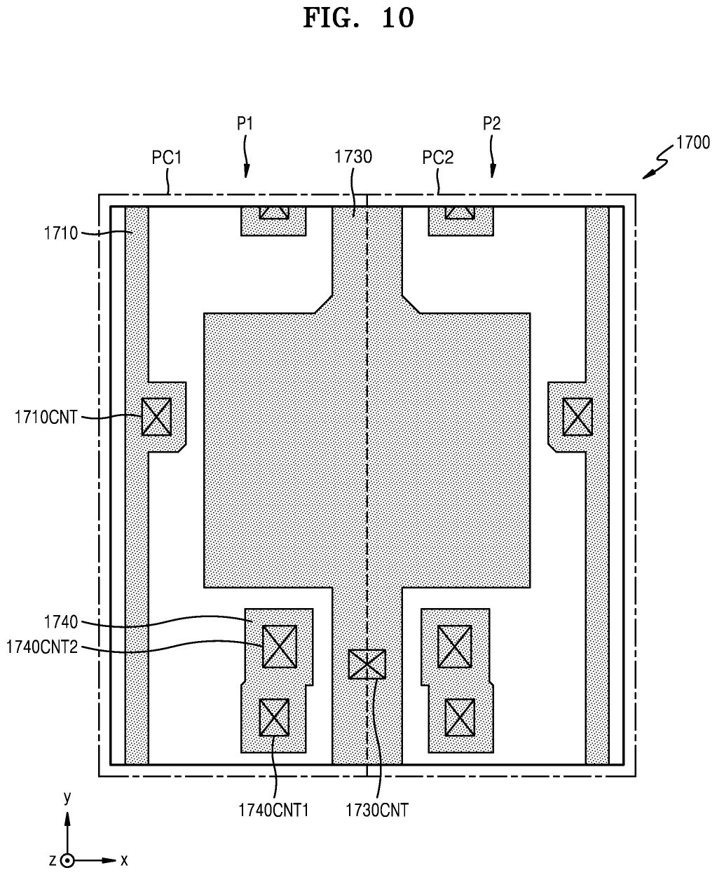

The printed circuit board 30 is configured to transfer signals of a controller (not shown) or power to the display panel 10. Control signals generated by the controller may be respectively transferred to the driving circuits through the printed circuit board 30. In addition, the controller may be configured to transfer a first power voltage ELVDD (see FIG. 2) to the driving power supply line and transfer a second power voltage ELVSS (see FIG. 2) to the electrode power supply line. The first power voltage ELVDD (or a driving voltage) may be transferred to each pixel through a driving power supply line 1730 (see FIG. 10) connected to the driving power supply line, and the second power voltage ELVSS (or a common voltage) may be transferred to an opposite electrode 230 (see FIG. 11) of the pixel connected to the electrode power supply line. The electrode power supply line may have a loop shape having one open side and have a shape partially surrounding the display area DA.

The controller may be configured to generate data signals, and the generated data signals may be transferred to the pixel through the driving chip 20 and a data line 1710 (see FIG. 10).

For reference, a “line” may mean a “wiring”. This is applicable to embodiments below and modifications thereof.

FIG. 2 is an equivalent circuit diagram of one pixel P included in the display apparatus of FIG. 1. As shown in FIG. 2, one pixel P may include a pixel circuit PC and an organic light-emitting diode OLED electrically connected to the pixel circuit PC.

As shown in FIG. 2, the pixel circuit PC may include a plurality of thin-film transistors T1, T2, T3, T4, T5, T6, and T7, and a storage capacitor Cst. The plurality of thin-film transistors T1, T2, T3, T4, T5, T6, and T7, and the storage capacitor Cst may be connected to signal lines, which include SL1, SL2, SLp, SLn, EL, and DL, a first initialization voltage line VL1, a second initialization voltage line VL2, and a driving voltage supply line PL. At least one of the lines, for example, the driving voltage supply line PL may be shared by the pixels P adjacent to each other.

The plurality of thin-film transistors T1, T2, T3, T4, T5, T6, and T7 may include a driving transistor T1, a switching transistor T2, a compensation transistor T3, a first initialization transistor T4, an operation control transistor T5, an emission control transistor T6, and a second initialization transistor T7.

The organic light-emitting diode OLED may include a pixel electrode and an opposite electrode. The pixel electrode of the organic light-emitting diode OLED may be connected to the driving transistor T1 through the emission control transistor T6 to receive a driving current, and the opposite electrode may be configured to receive the second power voltage ELVSS. The organic light-emitting diode OLED may be configured to generate light of brightness corresponding to the driving current.

Some of the plurality of thin-film transistors T1, T2, T3, T4, T5, T6, and T7 may be n-channel metal oxide semiconductor (NMOS) field-effect transistors (n-channel MOSFETs), and the rest may be p-channel metal oxide semiconductor (PMOS) field-effect transistors (p-channel MOSFETs). As an example, among the plurality of thin-film transistors T1, T2, T3, T4, T5, T6, and T7, the compensation transistor T3 and the first initialization transistor T4 may be n-channel MOSFETs (NMOS), and the rest may be p-channel MOSFETs (PMOS). Alternatively, among the plurality of thin-film transistors T1, T2, T3, T4, T5, T6, and T7, the compensation transistor T3, the first initialization transistor T4, and the second initialization transistor T7 may be n-channel MOSFETs (NMOSs), and the rest may be p-channel MOSFETs (PMOSs). Alternatively, all of the plurality of thin-film transistors T1, T2, T3, T4, T5, T6, and T7 may be NMOSs or PMOSs. The plurality of thin-film transistors T1, T2, T3, T4, T5, T6, and T7 may each include amorphous silicon or polycrystalline silicon. When needed, a thin-film transistor, which is an NMOS, may include an oxide semiconductor. Hereinafter, for convenience of description, the case where the compensation transistor T3 and the first initialization transistor T4 are NMOSs including an oxide semiconductor, and the rest are PMOSs, is described.

The signal lines may include a first scan line SL1, a second scan line SL2, a previous scan line SLp, a next scan line SLn (collectively marked as scan lines SL in FIG. 2) an emission control line EL, and a data line DL, wherein the first scan line SL1 is configured to transfer a first scan signal Sn, the second scan line SL2 is configured to transfer a second scan signal Sn′, the previous scan line SLp is configured to transfer a previous scan signal Sn−1 to the first initialization transistor T4, the next scan line SLn is configured to transfer a next scan signal Sn+1 to the second initialization transistor T7, the emission control line EL is configured to transfer an emission control signal En to the operation control transistor T5 and the emission control transistor T6, and the data line DL crosses the first scan line SL1 and is configured to transfer a data signal Dm.

The driving voltage supply line PL may be configured to transfer the driving voltage ELVDD to the driving transistor T1, the first initialization voltage line VL1 may be configured to transfer a first initialization voltage Vint1 initializing the driving transistor T1, and the second initialization voltage line VL2 may be configured to transfer a second initialization voltage Vint2 initializing a pixel electrode of the organic light-emitting diode OLED.

A driving gate electrode of the driving transistor T1 may be connected to the storage capacitor Cst through a second node N2, one of a source region and a drain region of the driving transistor T1 may be connected to the driving voltage supply line PL through the operation control transistor T5 via a first node N1, and the other of the source region and the drain region of the driving transistor T1 may be electrically connected to the pixel electrode of the organic light-emitting diode OLED through the emission control transistor T6 via a third node N3. The driving transistor T1 may be configured to receive a data signal Dm and supply a driving current to the organic light-emitting diode OLED according to a switching operation of the switching transistor T2. That is, the driving transistor T1 may be configured to control the amount of current flowing from the first node N1 to the organic light-emitting diode OLED in response to a voltage applied to the second node N2 and changed by a data signal Dm, the first node N1 being electrically connected to the driving voltage supply line PL.

A switching gate electrode of the switching transistor T2 may be connected to the first scan line SL1 configured to transfer a first scan signal Sn, one of a source region and a drain region of the switching transistor T2 may be connected to the data line DL, and the other of the source region and the drain region of the switching transistor T2 may be connected to the driving transistor T1 through the first node N1 and connected to the driving voltage supply line PL through the operation control transistor T5. The switching transistor T2 may be configured to transfer a data signal Dm from the data line DL to the first node N1 in response to a voltage applied to the first scan line SL1. That is, the switching transistor T2 may perform a switching operation of being turned on according to a first scan signal Sn transferred through the first scan line SL1 and transferring a data signal Dm to the driving transistor T1 through the first node N1, the data signal Dm being transferred through the data line DL.

A compensation gate electrode of the compensation transistor T3 is connected to the second scan line SL2. One of a source region and a drain region of the compensation transistor T3 may be connected to the pixel electrode of the organic light-emitting diode OLED through the emission control transistor T6 via the third node N3. The other of the source region and the drain region of the compensation transistor T3 may be connected to a first capacitor electrode CE1 of the storage capacitor Cst, and the driving gate electrode of the driving transistor T1 through the second node N2. The compensation transistor T3 may diode-connect the driving transistor T1 by being turned on according to a second scan signal Sn′ received through the second scan line SL2.

A first initialization gate electrode of the first initialization transistor T4 may be connected to the previous scan line SLp. One of a source region and a drain region of the first initialization transistor T4 may be connected to the first initialization voltage line VL1. The other of the source region and the drain region of the first initialization transistor T4 may be connected to the first capacitor electrode CE1 of the storage capacitor Cst, and the driving gate electrode of the driving transistor T1 through the second node N2. The first initialization transistor T4 may be configured to apply the first initialization voltage Vint1 from the first initialization voltage line VL1 to the second node N2 according to a voltage applied to the previous scan line SLp. That is, the first initialization transistor T4 may be turned on according to a previous scan signal Sn−1 received through the previous scan line SLp and may perform an initialization operation of initializing the voltage of the driving gate voltage of the driving transistor T1 by transferring the first initialization voltage Vint1 to the driving gate electrode of the driving transistor T1.

An operation control gate electrode of the operation control transistor T5 may be connected to the emission control line EL, one of a source region and a drain region of the operation control transistor T5 may be connected to the driving voltage supply line PL, and the other of the source region and the drain region of the operation control transistor T5 may be connected to the driving transistor T1 and the switching transistor T2 through the first node N1.

An emission control gate electrode of the emission control transistor T6 may be connected to the emission control line EL, one of a source region and a drain region of the emission control transistor T6 may be connected to the driving transistor T1 and the compensation transistor T3 through the third node N3, and the other of the source region and the drain region of the emission control transistor T6 may be electrically connected to the pixel electrode of the organic light-emitting diode OLED.

The operation control transistor T5 and the emission control transistor T6 may be simultaneously turned on according to an emission control signal En transferred through the emission control line EL, the driving voltage ELVDD is transferred to the organic light-emitting diode OLED, and the driving current flows through the organic light-emitting diode OLED.

A second initialization gate electrode of the second initialization transistor T7 may be connected to the next scan line SLn, one of a source region and a drain region of the second initialization transistor T7 may be connected to the pixel electrode of the organic light-emitting diode OLED, and the other of the source region and the drain region of the second initialization transistor T7 may be electrically connected to the second initialization voltage line VL2 to receive the second initialization voltage Vint2. The second initialization transistor T7 is turned on according to a next scan signal Sn+1 transferred through the next scan line SLn and initializes the pixel electrode of the organic light-emitting diode OLED. The next scan line SLn may be the same as the first scan line SL1. In this case, the relevant scan line may be configured to transfer the same electrical signals with a time difference, and thus, may serve as the first scan line SL1 and the next scan line SLn. That is, the next scan line SLn may be the first scan line of a pixel which is a pixel adjacent to the pixel P shown in FIG. 2 and electrically connected to the data line DL.

As shown in FIG. 2, the second initialization transistor T7 may be connected to the first scan line SL1. However, the embodiment is not limited thereto and the second initialization transistor T7 may be connected to the emission control line EL and driven according to an emission control signal En.

The storage capacitor Cst may include the first capacitor electrode CE1 and a second capacitor electrode CE2. The first capacitor electrode CE1 of the storage capacitor Cst is connected to the driving gate electrode of the driving transistor T1 through the second node N2, and the second capacitor electrode CE2 of the storage capacitor Cst is connected to the driving voltage supply line PL. The storage capacitor Cst may be configured to store charge corresponding to a difference between a voltage of the driving gate electrode of the driving transistor T1 and the driving voltage ELVDD.

A specific operation of each pixel P according to an embodiment is described below.

When a previous scan signal Sn−1 is supplied through the previous scan line SLp during an initialization period, the first initialization transistor T4 is turned on according to the previous scan signal Sn−1, and the driving transistor T1 is initialized by the first initialization voltage Vint1 supplied from the first initialization voltage line VL1.

When a first scan signal Sn and a second scan signal Sn′ are supplied through the first scan line SL1 and the second scan line SL2 during a data programming period, the switching transistor T2 and the compensation transistor T3 are turned on according to the first scan signal Sn and the second scan signal Sn′. In this case, the driving transistor T1 is diode-connected and forward-biased by the compensation transistor T3 that is turned on. Then, a compensation voltage Dm+Vth (Vth has a (−) value) is applied to the driving gate electrode of the driving transistor T1, wherein the compensation voltage Dm+Vth is a voltage reduced by a threshold voltage Vth of the driving transistor T1 from a data signal Dm supplied from the data line DL. The driving voltage ELVDD and the compensation voltage Dm+Vth are respectively applied to two opposite ends of the storage capacitor Cst, and charge corresponding to a difference between voltages of the two opposite ends is stored in the storage capacitor Cst.

During an emission period, the operation control transistor T5 and the emission control transistor T6 are turned on according to an emission control signal En supplied from the emission control line EL. The driving current corresponding to a voltage difference between the voltage of the driving gate electrode of the driving transistor T1 and the driving voltage ELVDD occurs, and the driving current is supplied to the organic light-emitting diode OLED through the emission control transistor T6.

As described above, some of the plurality of thin-film transistors T1, T2, T3, T4, T5, T6, and T7 may include an oxide semiconductor. As an example, the compensation transistor T3 and the first initialization transistor T4 may include an oxide semiconductor.

Because polycrystalline silicon has high reliability, it is possible to accurately control the flow of an intended current. Accordingly, the driving transistor T1 directly influencing the brightness of the display apparatus may include a semiconductor layer including polycrystalline silicon having high reliability, and thus, a high-resolution display apparatus may be implemented through this configuration. Because an oxide semiconductor has high carrier mobility and a low leakage current, a voltage drop is not large even when a driving time is long. That is, in the oxide semiconductor, because a color change of an image according to a voltage drop is not large even while the display apparatus is driven in low frequencies, the display apparatus may be driven in low frequencies. Accordingly, by allowing the compensation transistor T3 and the first initialization transistor T4 to include an oxide semiconductor, a display apparatus in which the occurrence of a leakage current is prevented, and simultaneously, with a reduced power consumption may be implemented.

Because the oxide semiconductor is sensitive to light, a change in the amount of current may occur due to externa light. Accordingly, external light may be absorbed or reflected by disposing a metal layer under the oxide semiconductor. Accordingly, gate electrodes of each of the compensation transistor T3 and the first initialization transistor T4 may be respectively disposed on and under the oxide semiconductor layer. That is, when viewed in a direction (a z axis direction) perpendicular to the upper surface of the substrate 100, the metal layer disposed under the oxide semiconductor may overlap the oxide semiconductor.

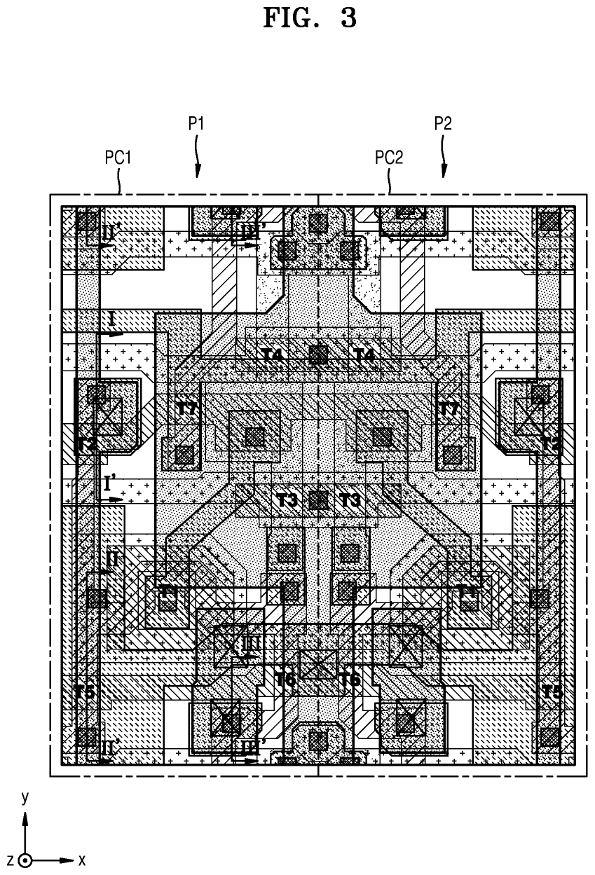

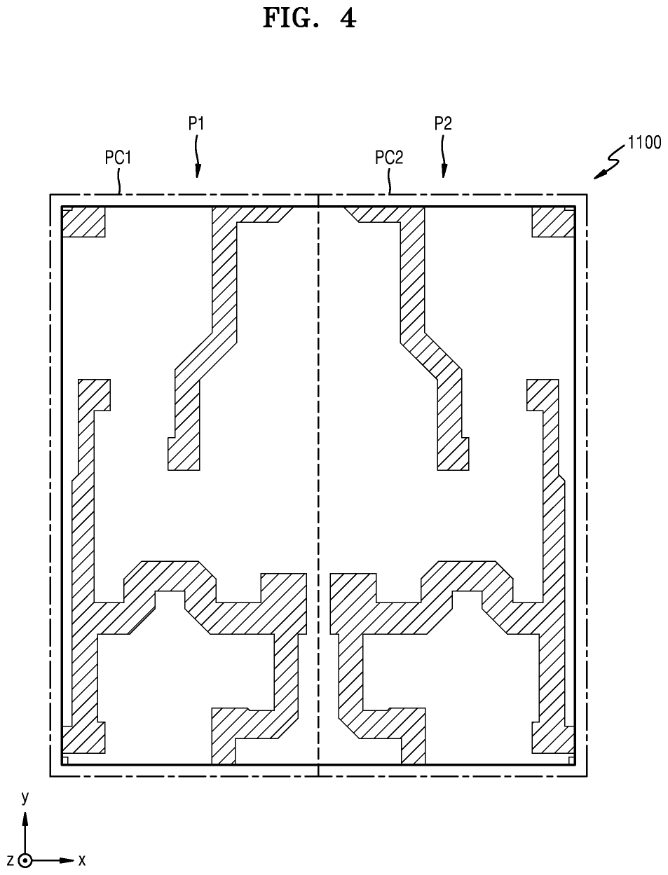

FIG. 3 is a schematic configuration view of positions of the thin-film transistors T1 to T7, the storage capacitor Cst and the like in pixels included in the display apparatus of FIG. 1, FIGS. 4 to 10 are schematic configuration views of elements such as the thin-film transistors T1 to T7 and the storage capacitor Cst, for each layer, of the display apparatus shown in FIG. 3, and FIG. 11 is a schematic cross-sectional view of the display apparatus shown in FIG. 3, taken along lines I-I′, II-II′, and III-III′.

As shown in the drawings, the display apparatus may include a first pixel P1 and a second pixel P2 adjacent to each other. The first pixel P1 and the second pixel P2 may be approximately symmetrical to each other with respect to a virtual line as shown in FIG. 3 and the like. However, the embodiment is not limited thereto and the first pixel P1 and the second pixel P2 may not be symmetrical to each other but may have the same construction or have various different constructions.

The first pixel P1 may include a first pixel circuit PC1, and the second pixel P2 may include a second pixel circuit PC2. Hereinafter, for convenience of description, although some of conductive patterns are described based on the first pixel circuit PC1, these conductive patterns may be approximately symmetrically arranged in the second pixel circuit PC2.

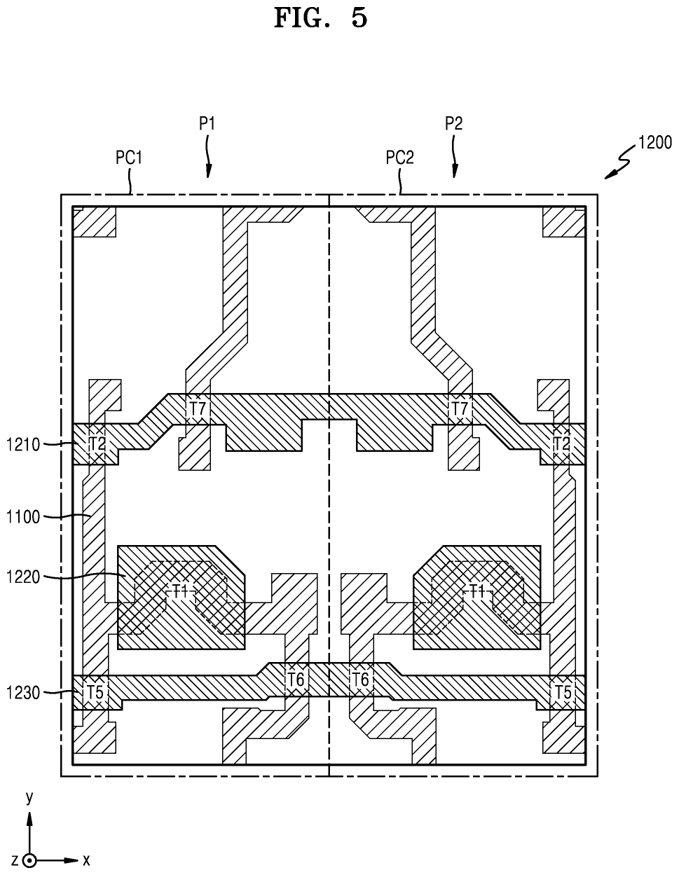

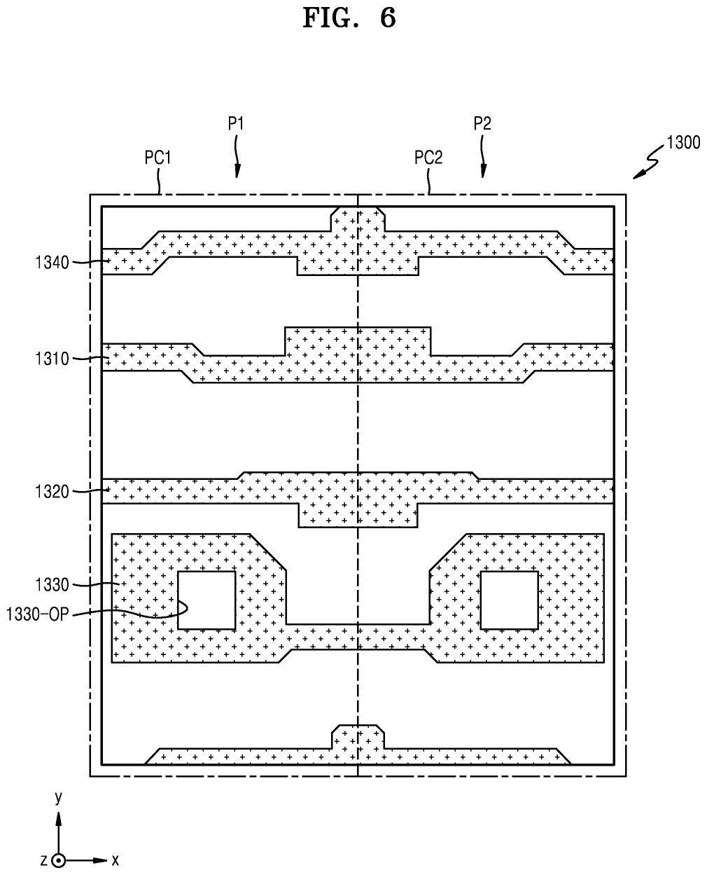

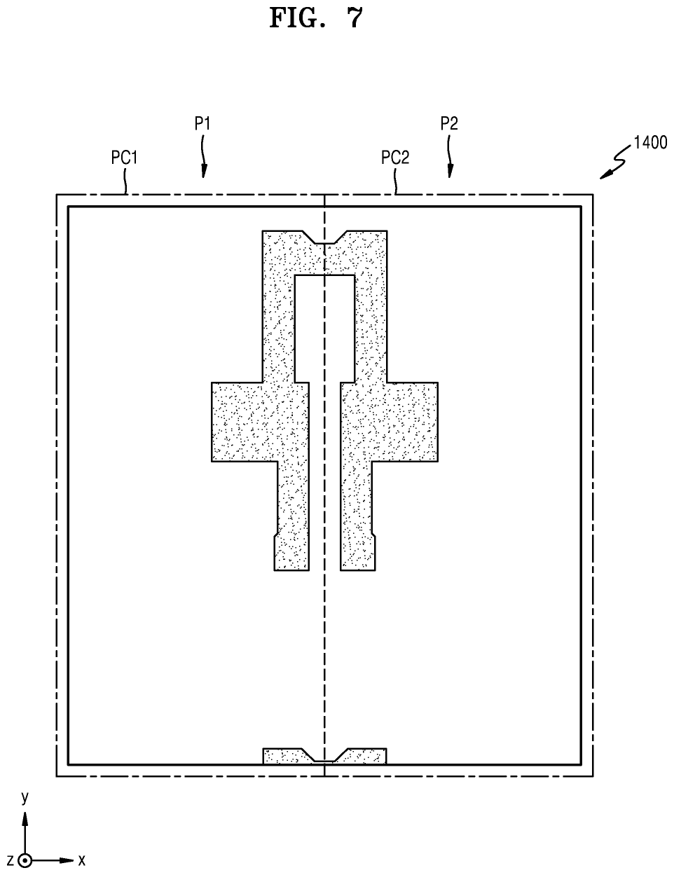

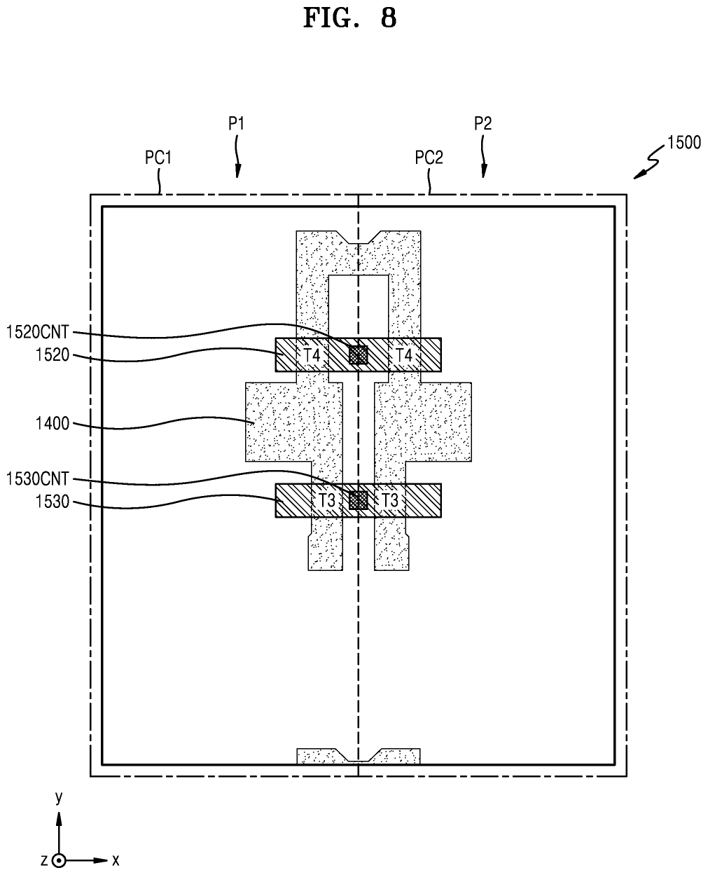

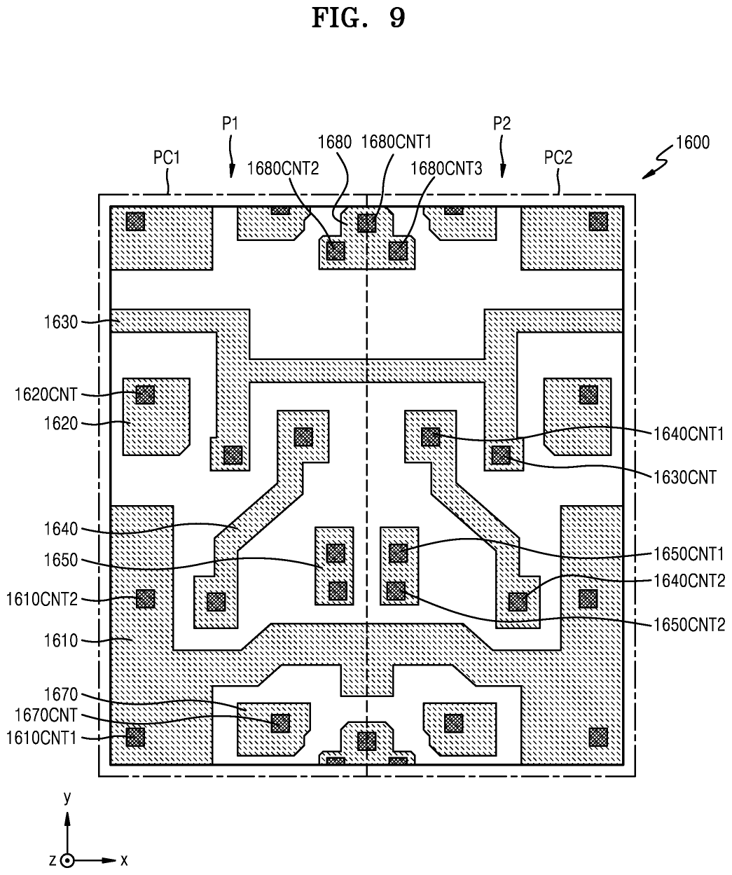

As sequentially shown in FIGS. 4 to 10, in a direction away from the substrate 100, a first semiconductor layer 1100 of FIG. 4, a first gate layer 1200 of FIG. 5, a second gate layer 1300 of FIG. 6, a second semiconductor layer 1400 of FIG. 7, a third gate layer 1500 of FIG. 8, a first source-drain layer 1600 of FIG. 9, and a second source-drain layer 1700 of FIG. 10 are arranged.

Insulating layers may be interposed between these layers. Specifically, as shown in FIG. 11, a first buffer layer 111 may be interposed between the substrate 100 and the first semiconductor layer 1100 of FIG. 4, a first gate insulating layer 113 may be interposed between the first semiconductor layer 1100 of FIG. 4 and the first gate layer 1200 of FIG. 5, a second gate insulating layer 115 may be interposed between the first gate layer 1200 of FIG. 5 and the second gate layer 1300 of FIG. 6, a second buffer layer (not shown) may be interposed between the second gate layer 1300 of FIG. 6 and the second semiconductor layer 1400 of FIG. 7, a third gate insulating layer 117 may be interposed between the second semiconductor layer 1400 of FIG. 7 and the third gate layer 1500 of FIG. 8, a first source insulating layer 118 may be interposed between the third gate layer 1500 of FIG. 8 and the first source-drain layer 1600 of FIG. 9, and a second source insulating layer 119 may be interposed between the first source-drain layer 1600 of FIG. 9 and the second source-drain layer 1700 of FIG. 10.

The buffer layer 111, the first gate insulating layer 113, the second gate insulating layer 115, the second buffer layer, the third gate insulating layer 117, the first source insulating layer 118, and the second source insulating layer 119 may each include an inorganic material. As an example, these layers may each include an inorganic insulating material including silicon oxide, silicon nitride, silicon oxynitride, aluminum oxide, titanium oxide, tantalum oxide, hafnium oxide and/or zinc oxide.

The display apparatus may include other layers in addition to these layers. Specifically, as shown in FIG. 11, a first interlayer insulating layer 121 may be interposed between the first semiconductor layer 1100 of FIG. 4 and the first gate insulating layer 113, a second interlayer insulating layer 122 may be interposed between the first gate layer 1200 of FIG. 5 and the second gate insulating layer 115, a third interlayer insulating layer 123 may be interposed between the second gate layer 1300 of FIG. 6 and the second buffer layer, a fourth interlayer insulating layer 124 may be interposed between the second semiconductor layer 1400 of FIG. 7 and the third gate insulating layer 117, a fifth interlayer insulating layer 125 may be interposed between the third gate layer 1500 of FIG. 8 and the first source insulating layer 118, and a sixth interlayer insulating layer 126 may be interposed between the first source-drain layer 1600 of FIG. 9 and the second source insulating layer 119. In addition, a planarization layer 128 may be disposed on the second source-drain layer 1700.

The first interlayer insulating layer 121, the second interlayer insulating layer 122, the third interlayer insulating layer 123, the fourth interlayer insulating layer 124, the fifth interlayer insulating layer 125, and the sixth interlayer insulating layer 126 may each include an organic insulating material. As an example, these layers may each include benzocyclobutene (BCB), polyimide, hexamethyldisiloxane (HMDSO), polymethylmethacrylate (PMMA), polystyrene, polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a mixture thereof. A layer including the organic insulating material may have an approximately flat upper surface.

The insulating layers may each have a single-layered structure or a multi-layered structure when needed. Elements on different layers may be electrically connected to each other through contact holes formed in the insulating layers.

The first buffer layer 111 may be disposed on the substrate 100. The first buffer layer 111 may be configured to prevent metal atoms, impurities, and/or the like from substrate 100 from diffusing in a direction to the first semiconductor layer 1100 disposed thereon. In addition, the first buffer layer 111 may allow the first semiconductor layer 1100 to be uniformly crystallized by adjusting a providing speed of heat during a crystallization process for forming the first semiconductor layer 1100.

As shown in FIG. 4, the first semiconductor layer 1100 may be disposed on the first buffer layer 111. The first semiconductor layer 1100 may include a silicon semiconductor. As an example, the first semiconductor layer 1100 may include amorphous silicon or polycrystalline silicon. Specifically, the first semiconductor layer 1100 may include polycrystalline silicon crystallized at low temperature. When needed, ions may be implanted in at least a portion of the first semiconductor layer 1100.

Because the driving transistor T1, the switching transistor T2, the operation control transistor T5, the emission control transistor T6, and the second initialization transistor T7 may be PMOSs as described above, in this case, the thin-film transistors T1, T2, T5, T6, and T7 are arranged along the first semiconductor layer 1100 as shown in FIG. 4. In addition, the first semiconductor layer 1100 may have a shape extending in the first direction (a +y direction) as a whole.

When viewed in a direction (a z axis direction) perpendicular to the substrate 100, the shape of the first semiconductor layer 1100 may correspond to the shape of the first buffer layer 111 and overlap the first buffer layer 111. As an example, an insulating layer may be formed on the substrate 100 to correspond to the entire surface of the substrate 100, a semiconductor layer may be formed on the insulating layer to correspond to the entire surface of the substrate 100, and then, the first buffer layer 111 and the first semiconductor layer 1100 may be formed by simultaneously patterning the insulating layer and the semiconductor layer using a photoresist and the like. Accordingly, as shown in FIG. 11, the lateral surface of the first semiconductor layer 1100 and the lateral surface of the first buffer layer 111 may be flush.

As described above, the first interlayer insulating layer 121 may cover the first semiconductor layer 1100. The first gate layer 1200 shown in FIG. 5 may be disposed on the first interlayer insulating layer 121. As described above, the first gate insulating layer 113 may be interposed between the first gate layer 1200 and the first interlayer insulating layer 121. For convenience, FIG. 5 shows the first gate layer 1200 together with the first semiconductor layer 1100.

When viewed in a direction (the z axis direction) perpendicular to the substrate 100, the shape of the first gate layer 1200 may correspond to the shape of the first gate insulating layer 113, and the first gate layer 1200 may overlap the first gate insulating layer 113. As shown in FIG. 11, the lateral surface of the first gate layer 1200 and the lateral surface of the first gate insulating layer 113 may form a continuous surface. The patterning of the first gate layer 1200 and the first gate insulating layer 113 is described below.

The first gate layer 1200 may include a first gate line 1210, a first gate electrode 1220, and a second gate line 1230.

The first gate line 1210 may extend in a second direction (a +x direction). The first gate line 1210 may be the first scan line SL1 or the next scan line SLn of FIG. 2. That is, in the first pixel P1 as shown in FIG. 5, the first gate line 1210 may correspond to the first scan line SL1 of FIG. 2, and in a pixel arranged adjacent to the first pixel P1 in the first direction (the +y direction), the first gate line 1210 may be the next scan line SLn of FIG. 2. Accordingly, first scan signals Sn and next scan signals Sn+1 may be applied to the pixels through the first gate line 1210. Portions of the first gate line 1210 overlapping the first semiconductor layer 1100 may be a switching gate electrode of the switching transistor T2 and a second initialization gate electrode of the second initialization transistor T7.

A first gate electrode 1220 may have an isolated shape. The first gate electrode 1220 may be a driving gate electrode of the driving transistor T1. For reference, a portion of the first semiconductor layer 1100 covered by the first gate electrode 1220 and a neighboring portion may be a driving semiconductor layer.

The second gate line 1230 may extend in the second direction (the +x direction). The second gate line 1230 may correspond to the emission control line EL of FIG. 2. Portions of the second gate line 1230 overlapping the first semiconductor layer 1100 may be an operation control gate electrode of the operation control transistor T5 and an emission control gate electrode of the emission control gate electrode T6. Emission control signals En may be applied to the pixels through the second gate line 1230.

The first gate layer 1200 may include metal, an alloy, a conductive metal oxide, a transparent conductive material, and/or the like. As an example, the first gate layer 1200 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. The first gate layer 1200 may have a multi-layered structure. As an example, the first gate layer 1200 may include a conductive pattern and a transparent conductive layer, wherein the conductive pattern has a single Al structure, a two-layered structure of Mo/Al, or a three-layered structure of Mo/Al/Mo, and the transparent conductive layer is disposed on the conductive pattern and includes ITO or IZO. It is shown in FIG. 11 that the first gate line 1210 includes a conductive pattern 1210a and a transparent conductive layer 1210b disposed on the conductive pattern 1210a, and the second gate line 1230 includes a conductive pattern 1230a and a transparent conductive layer 1230b disposed on the conductive pattern 1230a.

As described above, the second interlayer insulating layer 122 may cover the first gate layer 1200. The second gate layer 1300 shown in FIG. 6 may be disposed on the second interlayer insulating layer 122. As described above, the second gate insulating layer 115 may be interposed between the second gate layer 1300 and the second interlayer insulating layer 122.

When viewed in a direction (the z axis direction) perpendicular to the substrate 100, the shape of the second gate layer 1300 may correspond to the shape of the second gate insulating layer 115, and the second gate layer 1300 may overlap the second gate insulating layer 115. As shown in FIG. 11, the lateral surface of the second gate layer 1300 and the lateral surface of the second gate insulating layer 115 may be flush. The patterning of the second gate layer 1300 and the second gate insulating layer 115 is described below.

The second gate layer 1300 may include a third gate line 1310, a fourth gate line 1320, a capacitor upper electrode 1330, and a first initialization voltage line 1340 (that is, the first initialization voltage line VL1 of FIG. 2).

The third gate line 1310 may extend in the second direction (the +x direction). The third gate line 1310 may correspond to the previous scan line SLp of FIG. 2. When viewed in a direction (the z axis direction) perpendicular to the substrate 100, the third gate line 1310 may be apart from the first gate line 1210. Previous scan signals Sn−1 may be applied to the pixels through the third gate line 1310. A portion of the third gate line 1310 overlapping the second semiconductor layer 1400 described below may be a first initialization lower gate electrode of the first initialization transistor T4.

The fourth gate line 1320 may also extend in the second direction (the +x direction). The fourth gate line 1320 may correspond to the second scan line SL2 of FIG. 2. When viewed in a direction (the z axis direction) perpendicular to the substrate 100, the fourth gate line 1320 may be apart from the first gate line 1210 and the third gate line 1310. Second scan signals Sn′ may be applied to the pixels through the fourth gate line 1320. A portion of the fourth gate line 1320 overlapping the second semiconductor layer 1400 described below may be a compensation lower gate electrode of the compensation transistor T3.

The third gate line 1310 and the fourth gate line 1320 may be disposed under the second semiconductor layer 1400 described below with reference to FIG. 7 to not only serve as gate electrodes but also serve as lower protective metals protecting portions overlapping the third gate line 1310 and the fourth gate line 1320 of the second semiconductor layer 1400.

The capacitor upper electrode 1330 may overlap the first gate electrode 1220 and extend in the second direction (the +x direction). The capacitor upper electrode 1330 may correspond to the second capacitor electrode CE2 and form the storage capacitor Cst along with the first gate electrode 1220. The driving voltage ELVDD may be applied to the capacitor upper electrode 1330. In addition, a hole passing through the capacitor upper electrode 1330 may be formed in the capacitor upper electrode 1330, and at least a portion of the first gate electrode 1220 may overlap the hole.

The first initialization voltage line 1340, which is the first initialization voltage line VL1 of FIG. 2, may extend in the second direction (the +x direction). When viewed in a direction (the z axis direction) perpendicular to the substrate 100, the first initialization voltage line 1340 may be apart from the third gate line 1310. The first initialization voltage Vint1 may be applied to the pixels through the first initialization voltage line 1340. The first initialization voltage line 1340 may at least partially overlap the second semiconductor layer 1400 described below and be configured to transfer the first initialization voltage Vint1 to the second semiconductor layer 1400. The first initialization voltage line 1340 may be electrically connected to the second semiconductor layer 1400 through contact holes 1680CNT1, 1680CNT2, and 1680CNT3 described below with reference to FIG. 9.

The second gate layer 1300 may include metal, an alloy, a conductive metal oxide, a transparent conductive material, and/or the like. As an example, the second gate layer 1300 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. The second gate layer 1300 may have a multi-layered structure. As an example, the second gate layer 1300 may include a conductive pattern and a transparent conductive layer, wherein the conductive pattern has a single Al structure, a two-layered structure of Mo/Al, or a three-layered structure of Mo/Al/Mo, and the transparent conductive layer is disposed on the conductive pattern and includes ITO or IZO. It is shown in FIG. 11 that the third gate line 1310 includes a conductive pattern 1310a and a transparent conductive layer 1310b disposed on the conductive pattern 1310a, the fourth gate line 1320 includes a conductive pattern 1320a and a transparent conductive layer 1320b disposed on the conductive pattern 1320a, the capacitor upper electrode 1330 includes a conductive pattern 1330a and a transparent conductive layer 1330b disposed on the conductive pattern 1330a, and the first initialization voltage line 1340 includes a conductive pattern 1340a and a transparent conductive layer 1340b disposed on the conductive pattern 1340a.

As described above, the third interlayer insulating layer 123 may cover the second gate layer 1300. The second semiconductor layer 1400 shown in FIG. 7 may be disposed on the third interlayer insulating layer 123. As described above, the second buffer layer (not shown) may be interposed between the second semiconductor layer 1400 and the third interlayer insulating layer 123.

The second semiconductor layer 1400 may include an oxide semiconductor. As an example, the second semiconductor layer 1400 may include a Zn-oxide-based material. Specifically, the second semiconductor layer 1400 may include Zn oxide, In—Zn oxide, Ga—In—Zn oxide, and/or the like. Various modifications may be made. The second semiconductor layer 1400 may include an oxide semiconductor such as In—Ga—Zn—O (IGZO), In—Sn—Zn—O (ITZO), or In—Ga—Sn—Zn—O (IGTZO) semiconductor containing metal such as indium (In), gallium (Ga), and stannum (Sn) in ZnO.

The second semiconductor layer 1400 may be arranged on a layer different from a layer on which the first semiconductor layer 1100 is arranged. When viewed in a direction (the z axis direction) perpendicular to the substrate 100, the second semiconductor layer 1400 may not overlap the first semiconductor layer 1100.

Like the relationship between the first semiconductor layer 1100 and the first buffer layer 111, when viewed in a direction (the z axis direction) perpendicular to the substrate 100, the shape of the second semiconductor layer 1400 may correspond to the shape of the second buffer layer, and the second semiconductor layer 1400 may overlap the second buffer layer. As an example, an insulating layer may be formed on the third interlayer insulating layer 123 to correspond to the entire surface of the substrate 100, a semiconductor layer may be formed on the insulating layer to correspond to the entire surface of the substrate 100, and then, the second buffer layer and the second semiconductor layer 1400 may be formed by simultaneously patterning the insulating layer and the semiconductor layer using a photoresist and the like. Accordingly, the lateral surface of the second semiconductor layer 1400 and the lateral surface of the second buffer layer may be flush or form a continuous surface.

As described above, the fourth interlayer insulating layer 124 may cover the second semiconductor layer 1400. The third gate layer 1500 shown in FIG. 8 may be disposed on the fourth interlayer insulating layer 124. As described above, the third gate insulating layer 117 may be interposed between the third gate layer 1500 and the fourth interlayer insulating layer 124. For convenience, FIG. 8 shows the third gate layer 1500 together with the second semiconductor layer 1400.

When viewed in a direction (the z axis direction) perpendicular to the substrate 100, the shape of the third gate layer 1500 may correspond to the shape of the third gate insulating layer 117, and the third gate layer 1500 may overlap the third gate insulating layer 117. As shown in FIG. 11, the lateral surface of the third gate layer 1500 and the lateral surface of the third gate insulating layer 117 may be flush or form a continuous surface. The patterning of the third gate layer 1500 and the third gate insulating layer 117 is described below.

The third gate layer 1500 may include a fifth gate line 1520 and a sixth gate line 1530.

The fifth gate line 1520 may extend in the second direction (the +x direction) and have an isolated shape. When viewed in a direction (the z axis direction) perpendicular to the substrate 100, the fifth gate line 1520 may overlap the third gate line 1310. A portion of the fifth gate line 1520 overlapping the second semiconductor layer 1400 may be a first initialization upper gate electrode of the first initialization transistor T4. A portion of the second semiconductor layer 1400 overlapping the fifth gate line 1520 and a neighboring portion may be a first initialization semiconductor layer. The fifth gate line 1520 may be electrically connected to the third gate line 1310. As an example, the fifth gate line 1520 may be electrically connected to the third gate line 1310 through a contact hole 1520CNT formed in an insulating layer between the fifth gate line 1520 and the third gate line 1310. Accordingly, the fifth gate line 1520 and the third gate line 1310 may correspond to the previous scan line SLp of FIG. 2. A previous scan signal Sn−1 may be applied to the pixels through the fifth gate line 1520 and/or the third gate line 1310.

The sixth gate line 1530 may extend in the second direction (the +x direction) and have an isolated shape. When viewed in a direction (the z axis direction) perpendicular to the substrate 100, the sixth gate line 1530 may overlap the fourth gate line 1320. A portion of the sixth gate line 1530 overlapping the second semiconductor layer 1400 may be a compensation upper gate electrode of the compensation transistor T3. The sixth gate line 1530 may be electrically connected to the fourth gate line 1320. As an example, the sixth gate line 1530 may be electrically connected to the fourth gate line 1320 through a contact hole 1530CNT formed in an insulating layer between the sixth gate line 1530 and the fourth gate line 1320. Accordingly, the sixth gate line 1530 and the fourth gate line 1320 may correspond to the second scan line SL2 of FIG. 2. A second scan signal Sn′ may be applied to the pixels through the sixth gate line 1530 and/or the fourth gate line 1320.

The third gate layer 1500 may include metal, an alloy, a conductive metal oxide, a transparent conductive material, and/or the like. As an example, the third gate layer 1500 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. The third gate layer 1500 may have a multi-layered structure. As an example, the third gate layer 1500 may have a single Al layer, a two-layered structure of Mo/Al, or a three-layered structure of Mo/Al/Mo.

As described above, the fifth interlayer insulating layer 125 may cover the third gate layer 1500. The first source-drain layer 1600 shown in FIG. 9 may be disposed on the fifth interlayer insulating layer 125. As described above, the first source insulating layer 118 may be interposed between the first source-drain layer 1600 and the fifth interlayer insulating layer 125.

When viewed in a direction (the z axis direction) perpendicular to the substrate 100, the shape of the first source-drain layer 1600 may correspond to the shape of the first source insulating layer 118, and the first source-drain layer 1600 may overlap the first source insulating layer 118. As shown in FIG. 11, the lateral surface of the first source-drain layer 1600 and the lateral surface of the first source insulating layer 118 may be flush or form a continuous surface. The patterning of the first source-drain layer 1600 and the first source insulating layer 118 is described below.

The first source-drain layer 1600 may include a first connection electrode 1620, a second connection electrode 1610, a second initialization voltage line 1630, a third connection electrode 1670, a fourth connection electrode 1640, a fifth connection electrode 1650, and a sixth connection electrode 1680.

The first connection electrode 1620 may be electrically connected to the first semiconductor layer 1100 through a contact hole 1620CNT. A data signal Dm from the data line 1710 described below with reference to FIG. 10 may be transferred to the first semiconductor layer 1100 through the first connection electrode 1620 and applied to the switching transistor T2.

The second initialization voltage line 1630 may extend in the second direction (the +x direction). The second initialization voltage line 1630 corresponding to the second initialization voltage line VL2 of FIG. 2 may be configured to apply the second initialization voltage Vint2 to the pixels. Because the second initialization voltage line 1630 is electrically connected to the first semiconductor layer 1100 through a contact hole 1630CNT, the second initialization voltage Vint2 may be transferred to the first semiconductor layer 1100 and applied to the second initialization transistor T7.

The driving voltage ELVDD from the driving power supply line 1730 described below with reference to FIG. 10 is transferred to the second connection electrode 1610. The second connection electrode 1610 electrically connected to the first semiconductor layer 1100 through a contact hole 1610CNT1 may be configured to transfer the driving voltage ELVDD to the first semiconductor layer 1100, specifically, the operation control transistor T5. The second connection electrode 1610 electrically connected to the capacitor upper electrode 1330 (that is, the second capacitor electrode CE2 of FIG. 2) through a contact hole 1610CNT2, which is an additional contact hole, may be configured to transfer the driving voltage ELVDD to the capacitor upper electrode 1330. The second connection electrode 1610 may extend in the second direction (the +x direction) and be one body over the first pixel P1 and the second pixel P2.

The third connection electrode 1670 may be electrically connected to the first semiconductor layer 1100 through a contact hole 1670CNT. The third connection electrode 1670 may be configured to transfer a driving current from the first semiconductor layer 1100 or the second initialization voltage Vint2 to the organic light-emitting diode OLED.

The fourth connection electrode 1640 may be electrically connected to the second semiconductor layer 1400 through a contact hole 1640CNT1 formed in one side thereof. In addition, the fourth connection electrode 1640 is electrically connected to the first gate electrode 1220, which is a driving gate electrode, through a contact hole 1640CNT2 formed on another side thereof and passing through an opening 1330-OP of the capacitor upper electrode 1330. Accordingly, the fourth connection electrode 1640 may electrically connect the first initialization semiconductor layer, which is a portion of the second semiconductor layer 1400, to the driving gate electrode. The first initialization voltage Vint1 may be transferred to the first gate electrode 1220, which is the driving gate electrode, through the second semiconductor layer 1400 and the fourth connection electrode 1640.

The fifth connection electrode 1650 may electrically connect the second semiconductor layer 1400 and the first semiconductor layer 1100 to each other through contact holes 1650CNT1 and 1650CNT2 formed in one side and another side thereof. That is, the fifth connection electrode 1650 may electrically connect the compensation transistor T3 and the driving transistor T1 to each other.

The sixth connection electrode 1680 may be electrically connected to the second semiconductor layer 1400 through contact holes 1680CNT2 and 1680CNT3. In addition, the sixth connection electrode 1680 may be electrically connected to the first initialization voltage line 1340 of FIG. 6 through a contact hole 1680CNT1. Through this, the sixth connection electrode 1680 may be configured to transfer the first initialization voltage Vint1 from the first initialization voltage line 1340 to the first initialization transistor T4.

The first source-drain layer 1600 may include metal, an alloy, a conductive metal oxide, a transparent conductive material, and/or the like. As an example, the first source-drain layer 1600 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. The first source-drain layer 1600 may have a multi-layered structure. As an example, the first source-drain layer 1600 may include a conductive pattern and a transparent conductive layer, wherein the conductive pattern has a single Al structure, a two-layered structure of Ti/Al, or a three-layered structure of Ti/Al/Ti, and the transparent conductive layer is disposed on the conductive pattern and includes ITO or IZO. It is shown in FIG. 11 that the first connection electrode 1620 includes a conductive pattern 1620a and a transparent conductive layer 1620b disposed on the conductive pattern 1620a, the second connection electrode 1610 includes a conductive pattern 1610a and a transparent conductive layer 1610b disposed on the conductive pattern 1610a, and the third connection electrode 1670 includes a conductive pattern 1670a and a transparent conductive layer 1670b disposed on the conductive pattern 1670a.

As described above, the sixth interlayer insulating layer 126 may cover the first source-drain layer 1600. The second source-drain layer 1700 shown in FIG. 10 may be disposed on the sixth interlayer insulating layer 126. As described above, the second source insulating layer 119 may be interposed between the second source-drain layer 1700 and the sixth interlayer insulating layer 126.

When viewed in a direction (the z axis direction) perpendicular to the substrate 100, the shape of the second source-drain layer 1700 may correspond to the shape of the second source insulating layer 119, and the second source-drain layer 1700 may overlap the second source insulating layer 119. In this case, as shown in FIG. 11, the lateral surface of the second source-drain layer 1700 and the lateral surface of the second source insulating layer 119 may be flush or form a continuous surface. The patterning of the second source-drain layer 1700 and the second source insulating layer 119 is described below.

The second source-drain layer 1700 may include the data line 1710, the driving power supply line 1730, and an upper connection electrode 1740.

The data line 1710 may extend in the first direction (the +y direction). The data line 1710 may correspond to the data line DL of FIG. 2. Because the data line 1710 is electrically connected to the first connection electrode 1620 through a contact hole 1710CNT, a data signal Dm from the data line 1710 may be transferred to the first semiconductor layer 1100 through the first connection electrode 1620 and applied to the switching transistor T2.

The driving power supply line 1730 may extend approximately in the first direction (the +y direction). The driving power supply line 1730 may correspond to the driving voltage supply line PL of FIG. 2. The driving power supply line 1730 may be configured to apply the driving voltage ELVDD to the pixels. Because the driving power supply line 1730 is electrically connected to the second connection electrode 1610 through a contact hole 1730CNT, the driving voltage ELVDD may be transferred to the operation control transistor T5 and the capacitor upper electrode 1330 as described above. The driving power supply line 1730 of the first pixel circuit PC1 may be integrated with the driving power supply line 1730 of the second pixel circuit PC2 adjacent thereto.

The upper connection electrode 1740 is electrically connected to the third connection electrode 1670 through a contact hole 1740CNT1. In addition, the upper connection electrode 1740 is connected to a pixel electrode 211 thereabove through a contact hole 1740CNT2 formed in an insulating layer disposed thereon. Accordingly, the driving current or the second initialization voltage Vint2 from the first semiconductor layer 1100 may be transferred to the pixel electrode 211 of the organic light-emitting diode OLED through the third connection electrode 1670 and the upper connection electrode 1740.

The second source-drain layer 1700 may include metal, an alloy, a conductive metal oxide, a transparent conductive material, and/or the like. As an example, the second source-drain layer 1700 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. The second source-drain layer 1700 may have a multi-layered structure. As an example, the second source-drain layer 1700 may include a conductive pattern and a transparent conductive layer, wherein the conductive pattern has a single Al structure, a two-layered structure of Ti/Al, or a three-layered structure of Ti/Al/Ti, and the transparent conductive layer is disposed on the conductive pattern and includes ITO or IZO. It is shown in FIG. 11 that the data line 1710 includes a conductive pattern 1710a and a transparent conductive layer 1710b disposed on the conductive pattern 1710a, and the upper connection electrode 1740 includes a conductive pattern 1740a and a transparent conductive layer 1740b disposed on the conductive pattern 1740a.

A planarization layer 128 may cover the second source-drain layer 1700 and be disposed on the sixth interlayer insulating layer 126. As described above, because the planarization layer 128 includes an organic insulating material, an upper surface thereof may be approximately flat. The organic light-emitting diode OLED may be disposed on the planarization layer 128. It is shown in FIG. 11 that the organic light-emitting diode OLED includes the pixel electrode 211, an intermediate layer 221, and an opposite electrode 330, wherein the intermediate layer 221 includes an emission layer.

The pixel electrode 211 may be a (semi) light-transmissive electrode or a reflective electrode. As an example, the pixel electrode 211 may include a reflective layer and a transparent or semi-transparent electrode layer on the reflective layer, wherein the reflective layer includes Ag, Mg, Al, Pt, Pd, Au, Ni, Nd, Ir, Cr, or compound thereof. The transparent or semi-transparent electrode layer may include at least one of indium tin oxide (ITO), indium zinc oxide (IZO), zinc oxide (ZnO), indium oxide (In₂O₃), indium gallium oxide (IGO), and aluminum zinc oxide (AZO). As an example, the pixel electrode 211 may have a three-layered structure of ITO/Ag/ITO.

A pixel-defining layer 129 may be disposed on the planarization layer 128. The pixel-defining layer 129 may prevent arcs and the like from occurring at the edges of each pixel electrode 211 by increasing a distance between the edges of each pixel electrode 211 and the opposite electrode 230 on the pixel electrode 210. That is, the pixel-defining layer 129 may expose the central portion of the pixel electrode 211 by having a pixel opening 129OP. The pixel-defining layer 129 may include an organic insulating material such as polyimide, an acrylic resin, benzocyclobutene, a phenolic resin, and the like and be formed by using spin coating and the like.

At least a portion of the intermediate layer 221 including the emission layer of the organic light-emitting diode OLED may be arranged in the pixel opening 129OP formed in the pixel-defining layer 129. An emission area of the organic light-emitting diode OLED may be defined by the pixel opening 129OP.

The intermediate layer 221 may include the emission layer. The emission layer may include an organic material including a fluorescent or phosphorous material emitting red, green, blue, or white light. The emission layer may include a polymer organic material or a low molecular weight organic material. Functional layers may be selectively further arranged under and on the emission layer, the functional layers including a hole transport layer (HTL), a hole injection layer (HIL), an electron transport layer (ETL), an electron injection layer (EIL), or a quantum-dot layer.

The emission layer may have a shape patterned to correspond to each of the pixel electrodes 211. Layers of the intermediate layer 221 other than the emission layer may be integrated over the pixel electrodes 211. However, various modifications may be made.

The opposite electrode 230 may be a light-transmissive electrode or a reflective electrode. As an example, the opposite electrode 230 may be a transparent or semi-transparent electrode and may include a metal thin film including Li, Ca, Al, Ag, Mg, In, Yb, or compound thereof such as LiF and having a small work function. In addition, the opposite electrode 230 may further include a transparent conductive oxide (TCO) layer such as ITO, indium zinc oxide (IZO), ZnO, or In₂O₃ disposed on the metal thin film. The opposite electrode 230 may be integrally formed over the entire surface of the display area DA and disposed on the intermediate layer 221 and the pixel-defining layer 129.

When external impact is applied to the display apparatus, cracks may occur in an inorganic insulating layer including an inorganic insulating material inside the display apparatus. In addition, the cracks occurring in one pixel area may grow along the inorganic insulating layer including the inorganic insulating material inside the display apparatus and extend to an adjacent pixel area. Accordingly, defects may occur in the plurality of pixels.

In contrast, in the display apparatus according to an embodiment, the layers including the inorganic insulating layer do not have a shape formed over the entire surface of the substrate 100 but are patterned to have a minimum area when viewed in a direction (the z axis direction) perpendicular to the substrate 100. That is, the first buffer layer 111, the first gate insulating layer 113, the second gate insulating layer 115, the second buffer layer, the third gate insulating layer 117, the first source insulating layer 118, and the second source insulating layer 119 do not have a shape over the entire surface of the substrate 100 but are patterned to have the same shape as the conductive layer thereon. Accordingly, in the display apparatus according to an embodiment, even when external impact is applied, a probability that cracks occur may be remarkably reduced. In addition, even when cracks occur in the insulating layer including the inorganic insulating material due to external impact, a possibility that the cracks may grow may be remarkably reduced.

For reference, each of the first interlayer insulating layer 121, the second interlayer insulating layer 122, the third interlayer insulating layer 123, the fourth interlayer insulating layer 124, the fifth interlayer insulating layer 125, the sixth interlayer insulating layer 126, and the planarization layer 128 included in the display apparatus according to an embodiment may have a shape correspond to the entire surface of the substrate 100. However, these layers include an organic insulating material. Accordingly, even when external impact is applied to the display apparatus, cracks do not occur in the insulating layer including the organic insulating material, or even though the cracks occur, an occurrence probability thereof is extremely low.

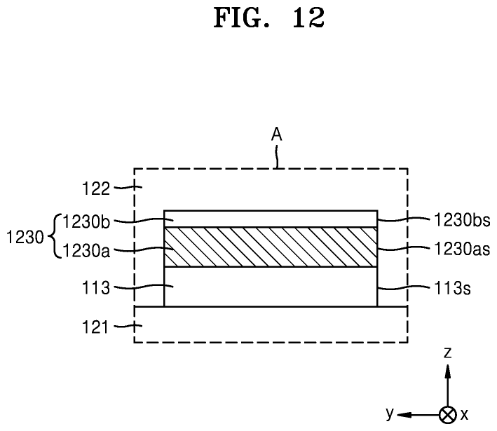

FIG. 12 is an enlarged cross-sectional view of a portion A of FIG. 11. As described above, the first gate layer 1200 may have a conductive pattern and a transparent conductive layer, wherein the conductive pattern has a single Al structure, a two-layered structure of Mo/Al, or a three-layered structure of Mo/Al/Mo, and the transparent conductive layer is disposed on the conductive pattern and includes ITO or IZO. It is shown in FIG. 12 that the second gate line 1230 includes a conductive pattern 1230a and a transparent conductive layer 1230b disposed on the conductive pattern 1230a. The first gate insulating layer 113, which is an inorganic insulating layer, may be disposed under the second gate line 1230, wherein the first gate insulating layer 113 is patterned to correspond to the second gate line 1230. The first gate insulating layer 113 and the second gate line 1230 may be disposed on the first interlayer insulating layer 121, which is an organic insulating layer.

Hereinafter, for convenience, the first interlayer insulating layer 121 is referred to as a first organic insulating layer 121, the first gate insulating layer 113 is referred to as a first inorganic insulating layer 113, the conductive pattern 1230a is referred to as a first conductive pattern 1230a, and the transparent conductive layer 1230b is referred to as a first transparent conductive layer 1230b. As described above, as shown in FIG. 12, the first inorganic insulating layer 113 may be patterned to have the same shape as the first conductive pattern 1230a, and the first transparent conductive pattern 1230b may be also patterned to have the same shape as the first conductive pattern 1230a. That is, an outer lateral surface 1230bs of the first transparent conductive layer 1230b and an outer lateral surface 1230as of the first conductive pattern 1230a may be flush or form a continuous surface. Furthermore, an outer lateral surface 113s of the first inorganic insulating layer 113 and an outer lateral surface 1230as of the first conductive pattern 1230a may also be flush or form a continuous surface.

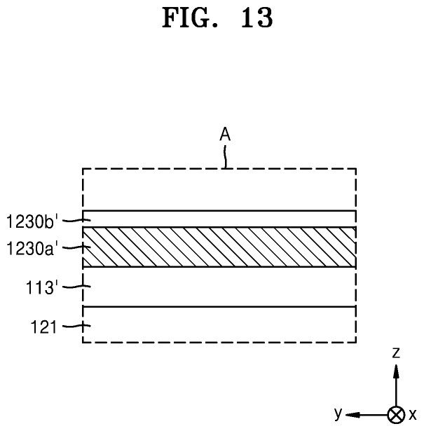

Hereinafter, a process of manufacturing the portion A is described with reference to FIGS. 13 to 17.

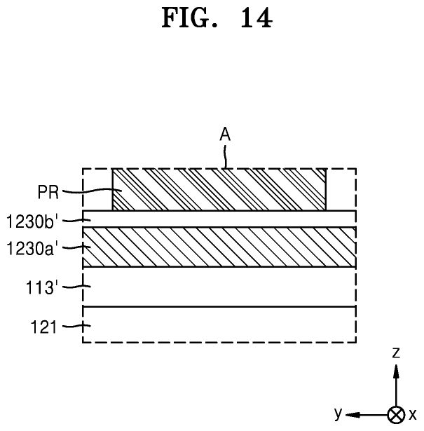

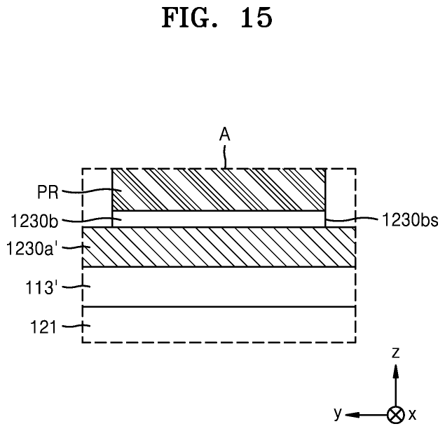

First, as shown in FIG. 13, an inorganic insulating material layer 113′ for the first inorganic insulating layer 113 is formed on the first organic insulating layer 121, a conductive layer 1230a′ for the first conductive pattern 1230a is formed on the inorganic insulating material layer 113′, and a transparent conductive layer 1230b′ for the first transparent conductive layer 1230b is formed on the conductive layer 1230a′. In addition, as shown in FIG. 14, a photoresist PR is formed on the transparent conductive layer 1230b′ to correspond to a portion to be formed as the first conductive pattern 1230a, and as shown in FIG. 15, the first transparent conductive layer 1230b is formed by removing an exposed portion of the transparent conductive layer 1230b′ that is not covered by the photoresist PR through wet etching.

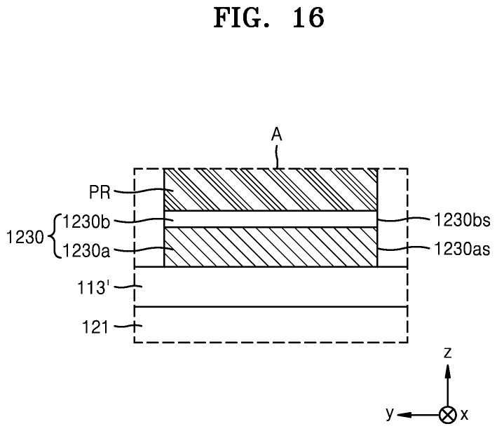

Subsequently, as shown in FIG. 16, the first conductive pattern 1230a is formed by removing a portion of the conductive layer 1230a′ that is exposed to the outside of the first transparent conductive layer 1230b through dry etching. The dry etching may be performed with the photoresist PR remaining as shown in FIG. 16, or with the photoresist PR removed. During the dry etching process, the first transparent conductive layer 1230b may serve as a mask shielding a portion to be formed as the first conductive pattern 1230a. Because the conductive layer 1230a′ is patterned through dry etching with the first transparent conductive layer 1230b serving as a mask as described above, the outer lateral surface 1230bs of the first transparent conductive layer 1230b and the outer lateral surface 1230as of the first conductive pattern 1230a may be flush or form a continuous surface. Accordingly, when viewed in a direction (the z axis direction) perpendicular to the substrate 100, the area of the first transparent conductive layer 1230b and the area of the first conductive pattern 1230a may be substantially equal to each other. The “area,” as used herein, is the area in the x-y plane.

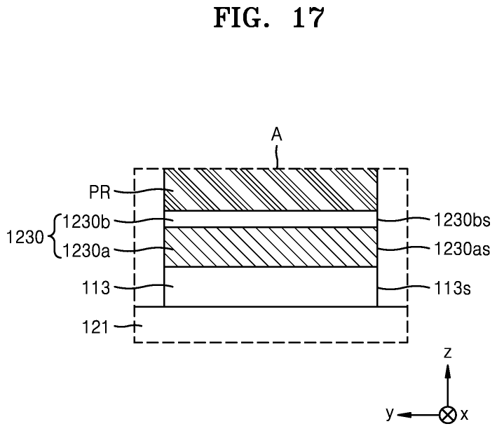

After the first conductive pattern 1230a is formed, as shown in FIG. 17, the first inorganic insulating layer 113 is formed by removing, through dry etching, a portion of the inorganic insulating material layer 113′ that is exposed to the outside of the first transparent conductive layer 1230b. The dry etching may be performed with the photoresist PR remaining as shown in FIG. 17, or with the photoresist PR removed. During the dry etching process, the first transparent conductive layer 1230b may serve as a mask shielding a portion to be formed as the first inorganic insulating layer 113. As described above, because the first transparent conductive layer 1230b includes indium tin oxide (ITO), indium zinc oxide (IZO), and/or the like, an etching rate of the inorganic insulating layer may be several tens of times, for example, 30 times the etching rate of the first transparent conductive layer 1230b during the dry etching process. Accordingly, the first transparent conductive layer 1230b may effectively serve as a mask shielding a portion to be formed as the first inorganic insulating layer 113.

Because the inorganic insulating material layer 113′ is patterned through dry etching with the first transparent conductive layer 1230b serving as a mask as described above, the outer lateral surface 1230bs of the first transparent conductive layer 1230b, the outer lateral surface 1230as of the first conductive pattern 1230a, and the outer lateral surface 113s of the first inorganic insulating layer 113 may be flush or form a continuous surface. Accordingly, when viewed in a direction (the z axis direction) perpendicular to the substrate 100, the area of the first transparent conductive layer 1230b, the area of the first conductive pattern 1230a, and the area of the first inorganic insulating layer 113 may be substantially equal to each other.

Up to this point, the process of forming the second gate line 1230 and the first gate insulating layer 113 thereunder has been described with reference to FIGS. 13 to 17. The first gate line 1210, the first gate electrode 1220, and the second gate line 1230 included in the first gate layer 1200 may be simultaneously formed through the same process. In addition, the second gate layer 1300 and the second gate insulating layer 115 thereunder may be formed through the process described with reference to FIGS. 13 to 17, and the third gate layer 1500 and the third gate insulating layer 117 thereunder may be formed through the process described with reference to FIGS. 13 to 17.

As an example, the fifth gate line 1520 may include a conductive pattern 1520a and a transparent conductive layer 1520b disposed on the conductive pattern 1520a, and the sixth gate line 1530 may include a conductive pattern 1530a and a transparent conductive layer 1530b disposed on the conductive pattern 1530a. The third gate insulating layer 117, which is an inorganic insulating layer, may be disposed under each of the fifth gate line 1520 and the sixth gate line 1530. A relationship between the fifth gate line 1520 and the third gate insulating layer 117 thereunder, and a relationship between the sixth gate line 1530 and the third gate insulating layer 117 thereunder may be the same as that described to the relationship between the second gate line 1230 and the first gate insulating layer 113 thereunder.

For reference, a process of forming the first semiconductor layer 1100 and the first buffer layer 111 thereunder may be similar to this. That is, an inorganic insulating material layer for forming the first buffer layer 111 may be formed to correspond to the entire surface of the substrate 100, and a semiconductor material layer for forming the first semiconductor layer 1100 may be formed on the inorganic insulating material layer to correspond to the entire surface of the substrate 100. Then, the first buffer layer 111 and the first semiconductor layer 1100 having the same shape when viewed in the direction (the z axis direction) perpendicular to the substrate 100 may be formed by patterning the semiconductor material layer and the inorganic insulating material layer using a photoresist and the like.

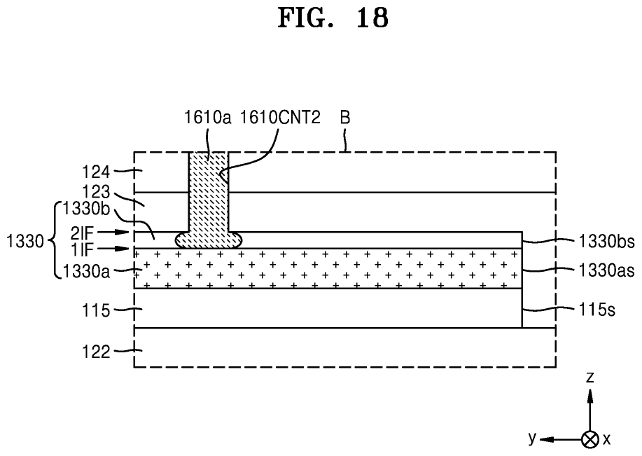

FIG. 18 is an enlarged cross-sectional view of a portion B of FIG. 11. As described above, the second gate layer 1300 may have a conductive pattern and a transparent conductive layer, wherein the conductive pattern has a single Al structure, a two-layered structure of Mo/Al, or a three-layered structure of Mo/Al/Mo, and the transparent conductive layer is disposed on the conductive pattern and includes ITO or IZO. It is shown in FIG. 18 that the capacitor upper electrode 1330 includes a conductive pattern 1330a and a transparent conductive layer 1330b disposed on the conductive pattern 1330a. The second gate insulating layer 115, which is an inorganic insulating layer, may be disposed under the capacitor upper electrode 1330, wherein the second gate insulating layer 115 is patterned to correspond to the capacitor upper electrode 1330. The second gate insulating layer 115 and the capacitor upper electrode 1330 may be disposed on the second interlayer insulating layer 122 covering the first gate layer 1200.

Hereinafter, for convenience, the second interlayer insulating layer 122 is referred to as the first organic insulating layer 122, the second gate insulating layer 115 is referred to as the first inorganic insulating layer 115, the conductive pattern 1330a is referred to as a first conductive pattern 1330a, and the transparent conductive pattern 1330b referred to as a first transparent conductive layer 1330b. As described above, as shown in FIG. 18, the first inorganic insulating layer 115 may be patterned to have the same shape as the first conductive pattern 1330a, and the first transparent conductive pattern 1330b may be also patterned to have the same shape as the first conductive pattern 1330a. That is, an outer lateral surface 1330bs of the first transparent conductive layer 1330b and an outer lateral surface 1330as of the first conductive pattern 1330a may be flush or form a continuous surface, and furthermore, an outer lateral surface 115s of the first inorganic insulating layer 115 and an outer lateral surface 1330as of the first conductive pattern 1330a may also be flush or form a continuous surface.

The third interlayer insulating layer 123, which may be referred to as a second organic insulating layer, may be disposed on the first organic insulating layer 122, and the second organic insulating layer 123 may cover the first transparent conductive layer 1330b. The fourth interlayer insulating layer 124, which may be referred to as a third organic insulating layer, may be disposed on the second organic insulating layer 123, and the fifth interlayer insulating layer 125, which may be referred to as a fourth organic insulating layer, may be disposed on the third organic insulating layer 124.

The first transparent conductive layer 1330b may expose a portion of the upper surface of the first conductive pattern 1330a by having a first hole. The second organic insulating layer 123 may have a second hole corresponding to the first hole. The third organic insulating layer 124 and the fourth organic insulating layer 125 may have an extension hole corresponding to the second hole. When viewed in the direction perpendicular to the substrate 100, the first hole, the second hole, and the extension hole may overlap each other. Each of the first hole, the second hole, and the extension hole may be a portion of the contact hole 1610CNT2 shown in FIG. 11 and/or FIG. 18.

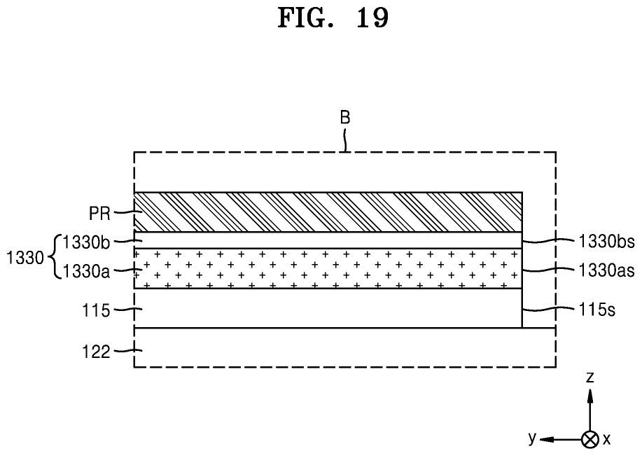

Hereinafter, a process of manufacturing the portion B is described with reference to FIGS. 19 to 22.

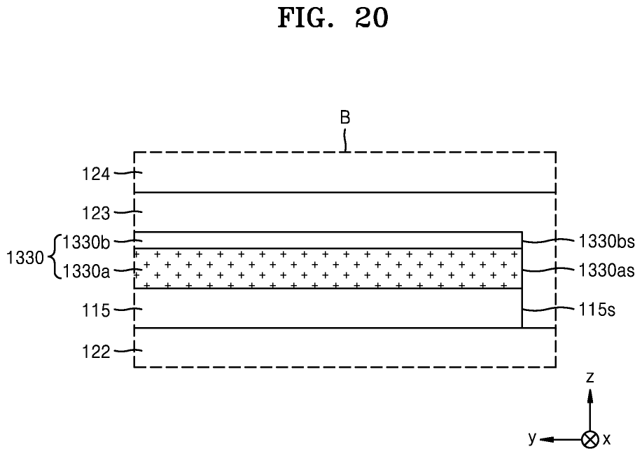

First, a stack body of the first inorganic insulating layer 115, the first conductive pattern 1330a, and the first transparent conductive layer 1330b sequentially stacked on the first organic insulating layer 122 may be formed through the same process described with reference to FIGS. 13 to 17. The photoresist PR may be present or may not present on the first transparent conductive layer 1330b. When the photoresist PR is present, the photoresist PR is removed. Then, as shown in FIG. 20, the second organic insulating layer 123 disposed on the first organic insulating layer 122, and the third organic insulating layer 124 disposed on the second organic insulating layer 123 may be formed to cover the stack body.

Before the third organic insulating layer 124 is formed, a process of forming the second buffer layer and the second semiconductor layer 1400 on the second organic insulating layer 123 may be performed. The third gate insulating layer 117 and the third gate layer 1500 that are sequentially stacked on the third organic insulating layer 124 (shown in FIG. 11) may be formed through the same process described with reference to FIGS. 13 to 17. The third gate layer 1500 may be a stack body of a conductive pattern and a transparent conductive layer. In addition, the fourth organic insulating layer 125 disposed on the third organic insulating layer 124 may be formed to cover the stack body. In addition, to form the first source insulating layer 118, which may be referred to as a second inorganic insulating layer, on the fourth organic insulating layer 125, an inorganic insulating material layer corresponding to the entire surface of the substrate 100 is formed.

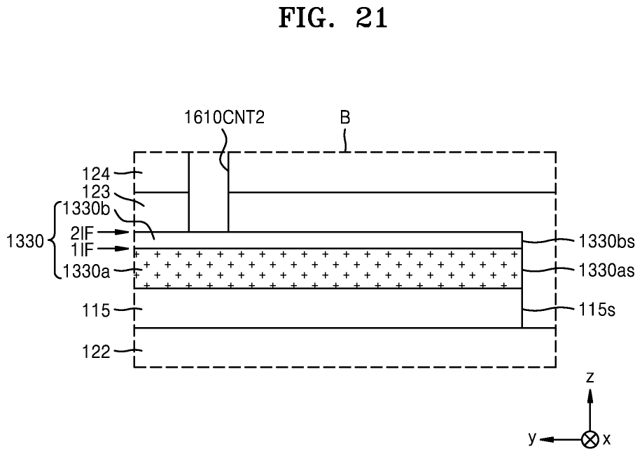

Then, as shown in FIG. 21, the contact hole 1610CNT2 is formed, wherein the contact hole 1610CNT2 passes through the second organic insulating layer 123, the third organic insulating layer 124, the fourth organic insulating layer 125, the inorganic insulating material layer, and the like to expose a portion of the upper surface of the first transparent conductive layer 1330b. The contact hole 1610CNT2 passing through the second organic insulating layer 123 and the third organic insulating layer 124 may be formed through dry etching that uses a photoresist. A portion of the contact hole 1610CNT2 corresponding to the second organic insulating layer 123 may be referred to as the second hole, a portion of the contact hole 1610CNT2 corresponding to the third organic insulating layer 124 and the fourth organic insulating layer 125 may be referred to as the extension hole, and a portion of the contact hole 1610CNT2 corresponding to the inorganic insulating material layer may be referred to as the third hole. In this meaning, the first hole, the second hole, the extension hole, and the third hole may correspond to each other. The first hole, the second hole, and the third hole may be simultaneously formed during the same process.

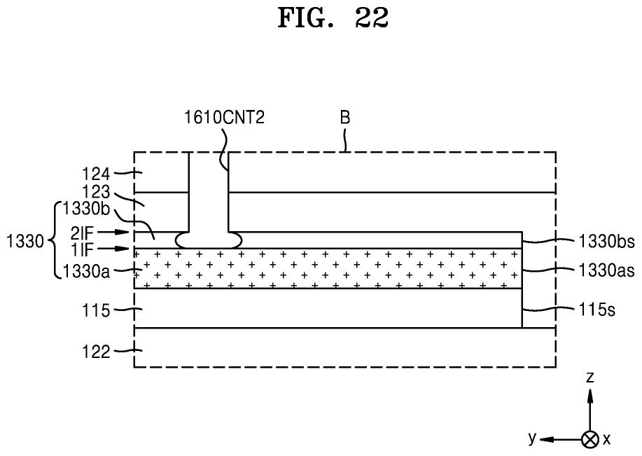

Subsequently, as shown in FIG. 22, the first hole may be formed in the first transparent conductive layer 1330b by removing a portion of the first transparent conductive layer 1330b exposed by the contact hole 1610CNT2 through wet etching. The first hole may be a portion of the contact hole 1610CNT2. Then, the first source insulating layer 118 and the second connection electrode 1610 may be formed by forming a conductive layer and a transparent conductive layer for forming the first source-drain layer 1600 on the inorganic insulating material layer similarly to the description made with reference to FIG. 13, and patterning the inorganic insulating material layer, the conductive layer, and the transparent conductive layer similarly to the description made with reference to FIG. 11, wherein the first source insulating layer 118 may be referred to as the second inorganic insulating layer, and the second connection electrode 1610 is disposed on the first source insulating layer 118 and includes the conductive pattern 1610a and the transparent conductive layer 1610b disposed on the conductive pattern 1610a. Accordingly, the edge of the first source insulating layer 118, which may be referred to as the second inorganic insulating layer, may be aligned with the edge of the conductive pattern 1610a, which may be referred to as the second conductive pattern, and the edge of the transparent conductive layer 1610b, which may be referred to as the second transparent conductive layer, may be flush with the edge of the conductive pattern 1610a. Furthermore, an outer lateral surface of the first insulating layer 118, an outer lateral surface of the conductive pattern 1610a, and an outer lateral surface of the transparent conductive layer 1610b may be flush or form a continuous surface, and when viewed in the direction (the z axis direction) perpendicular to the substrate 100, an area of the transparent conductive layer 1610b, an area of the conductive pattern 1610a, and an area of the first source insulating layer 118 thereunder may be equal to each other.

During this process, the contact hole 1610CNT2 is filled with the conductive layer when forming the conductive layer, and the conductive layer may be in contact with the upper surface of the first conductive pattern 1330a by the contact hole 1610CNT2. Consequently, the conductive pattern 1610a of the second connection electrode 1610, which may be referred to as the second conductive pattern disposed on the second organic insulating layer 123, the third organic insulating layer 124 and the like may fill the contact hole 1610CNT2 and be in contact with the upper surface of the first conductive pattern 1330a. The second conductive pattern 1610a may fill the first hole of the first transparent conductive layer 1330b, the second hole of the second organic insulating layer 123, the extension hole of the third organic insulating layer 124 and the fourth organic insulating layer 125, and the third hole of the first source insulating layer 118.

As described with reference to FIG. 22, the first hole may be formed in the first transparent conductive layer 1330b by removing a portion of the first transparent conductive layer 1330b exposed by the contact hole 1610CNT2 through wet etching. Because the first hole is formed through wet etching, an undercut phenomenon occurs and an area of the first hole formed in the first transparent conductive layer 1330b may be greater than an area of the second hole of the second organic insulating layer 123. Specifically, assuming that an interface between the first transparent conductive layer 1330b and the first conductive pattern 1330a is a first interface 1IF, and an interface between the first transparent conductive layer 1330b and the second organic insulating layer 123 is a second interface 2IF, an area of the first hole of the first transparent conductive layer 1330b in the second interface 2IF may be less than an area of the first hole of the first transparent conductive layer 1330b in a virtual plane (an xy-plane) between the first interface 1IF and the second interface 2IF. In this case, an area of the first transparent conductive layer 1330b in the second interface 2IF may be equal to an area of the second hole of the second organic insulating layer 123 in the second interface 2IF.

Up to this point, the process of forming the capacitor upper electrode 1330 and the second gate insulating layer 115 thereunder has been described with reference to FIGS. 19 and 22. The third gate line 1310, the fourth gate line 1320, the capacitor upper electrode 1330, and the first initialization voltage line 1340 included in the second gate line 1300 may be simultaneously formed during the same process.

When forming the second source-drain layer 1700, the method described with reference to FIGS. 13 to 17 is applicable. Accordingly, as shown in FIG. 11, the data line 1710 may include the conductive pattern 1710a and the transparent conductive layer 1710b disposed on the conductive pattern 1710a, and the upper connection electrode 1740 may include the conductive pattern 1740a and the transparent conductive layer 1740b disposed on the conductive pattern 1740a. The same applies to the driving power supply line 1730. The second source insulating layer 119, which is an inorganic insulating layer, may be disposed under each of the data line 1710, the driving power supply line 1730, and the upper connection electrode 1740. A relationship between the data line 1710 and the second insulating layer 119 thereunder, and a relationship between the upper connection electrode 1740 and the second insulating layer 119 thereunder may be the same as that described to the relationship between the second gate line 1230 and the first gate insulating layer 113 thereunder.

Because the conductive pattern 1710a of the data line 1710 is connected to the conductive pattern 1620a of the first connection electrode 1620 through the contact hole 1710CNT, the description with reference to FIGS. 18 to 22 in which the conductive pattern 1610a of the second connection electrode 1610 is connected to the conductive pattern 1330a of the capacitor upper electrode 1330 through the contact hole 1610CNT2 is applicable to this (except that the number of interlayer insulating layers is different). That is, the description of the first hole and the like formed in the transparent conductive layer 1330b of the capacitor upper electrode 1330 is applicable to the hole and the like formed in the transparent conductive layer 1620b of the first connection electrode 1620.

Because the conductive pattern 1740a of the upper connection electrode 1740 is connected to the conductive pattern 1670a of the third connection electrode 1670 through the contact hole 1740CNT1, the description with reference to FIGS. 18 to 22 in which the conductive pattern 1610a of the second connection electrode 1610 is connected to the conductive pattern 1330a of the capacitor upper electrode 1330 through the contact hole 1610CNT2 is applicable to this (except that the number of interlayer insulating layers is different). That is, the description of the first hole and the like formed in the transparent conductive layer 1330b of the capacitor upper electrode 1330 is applicable to the hole and the like formed in the transparent conductive layer 1670b of the third connection electrode 1670.

According to an embodiment having the above configuration, the display apparatus with excellent durability may be implemented. However, the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a first organic insulating layer disposed on the substrate;
a first conductive pattern disposed on the first organic insulating layer;
a first inorganic insulating layer interposed between the first organic insulating layer and the first conductive pattern and patterned to have a same shape as the first conductive pattern; and
a first transparent conductive layer disposed on the first conductive pattern and patterned to have a same shape as the first conductive pattern.

2. The display apparatus of claim 1, wherein an outer lateral surface of the first transparent conductive layer and an outer lateral surface of the first conductive pattern are flush.

3. The display apparatus of claim 1, wherein an outer lateral surface of the first transparent conductive layer, an outer lateral surface of the first conductive pattern, and an outer lateral surface of the first inorganic insulating layer are flush.

4. The display apparatus of claim 1, wherein, when viewed in a direction perpendicular to the substrate, an area of the first transparent conductive layer is equal to an area of the first conductive pattern.

5. The display apparatus of claim 1, wherein, when viewed in a direction perpendicular to the substrate, an area of the first transparent conductive layer, an area of the first conductive pattern, and an area of the first inorganic insulating layer are equal to each other.

6. The display apparatus of claim 1, wherein the first transparent conductive layer has a first hole exposing a portion of an upper surface of the first conductive pattern.

7. The display apparatus of claim 6, further comprising a second organic insulating layer disposed on the first organic insulating layer to cover the first transparent conductive layer, wherein the second organic insulating layer has a second hole aligned with the first hole.

8. The display apparatus of claim 7, wherein, when viewed in a direction perpendicular to the substrate, the second hole connects to the first hole and forms a hole that continuously extends through the second organic insulating layer and the first transparent conductive layer.

9. The display apparatus of claim 8, wherein an area of the first hole is greater than an area of the second hole, the area being measured in a plane that is parallel to a plane of a top surface of the substrate.

10. The display apparatus of claim 8, wherein an area of the first hole in a second interface between the first transparent conductive layer and the second organic insulating layer is less than an area of the first hole in a virtual plane that divides the first transparent conductive layer into two parts in a thickness direction of the display appartus.

11. The display apparatus of claim 10, wherein the area of the first hole in the second interface is equal to an area of the second hole in the second interface.

12. The display apparatus of claim 7, further comprising a second conductive pattern disposed on the second organic insulating layer, wherein the second conductive pattern is in contact with the upper surface of the first conductive pattern through the first hole and the second hole.

13. The display apparatus of claim 12, wherein the second conductive pattern fills the first hole and the second hole.

14. The display apparatus of claim 12, further comprising a second inorganic insulating layer interposed between the second organic insulating layer and the second conductive pattern, wherein an edge of the second inorganic insulating layer is aligned with an edge of the second conductive pattern.

15. The display apparatus of claim 14, wherein an outer lateral surface of the second conductive pattern is flush with an outer lateral surface of the second inorganic insulating layer.

16. The display apparatus of claim 14, wherein, when viewed in a direction perpendicular to the substrate, an area of the second conductive pattern is equal to an area of the second inorganic insulating layer.

17. The display apparatus of claim 14, wherein the second inorganic insulating layer has a third hole aligned with the second hole.

18. The display apparatus of claim 17, wherein the second conductive pattern is in contact with the upper surface of the first conductive pattern through the first hole, the second hole, and the third hole.

19. The display apparatus of claim 14, further comprising a second transparent conductive layer disposed on the second conductive pattern, wherein an edge of the second transparent conductive layer is flush with the edge of the second conductive pattern.

20. The display apparatus of claim 19, wherein an outer lateral surface of the second transparent conductive layer is flush with an outer lateral surface of the second conductive pattern.

21. The display apparatus of claim 19, wherein, when viewed in a direction perpendicular to the substrate, an area of the second transparent conductive layer is equal to an area of the second conductive pattern.
